(19) United States
(12) Patent Application Publication
(10) Pub. No.: US 2024/0124765 A1
(43) Pub. Date: Apr. 18, 2024

(54) QUANTUM DOT, COMPOSITION FOR PREPARING QUANTUM DOT COMPOSITE, QUANTUM DOT COMPOSITE, AND DISPLAY PANEL

(71) Applicant: SAMSUNG ELECTRONICS CO., LTD., Suwon-si (KR)

(72) Inventors: Jong Hoon WON, Suwon-si (KR); Deuk Kyu MOON, Suwon-si (KR); Shang Hyeun PARK, Suwon-si (KR); Tae-Gon KIM, Suwon-si (KR); Young Hoon LEE, Suwon-si (KR); Deuk Seok CHUNG, Suwon-si (KR)

(21) Appl. No.: 18/475,698

(22) Filed: Sep. 27, 2023

(30) Foreign Application Priority Data
Sep. 27, 2022 (KR) 10-2022-0122643

(51) Int. Cl. C09K 11/02; C08K 9/04; C09K 11/08; C09K 11/88; H01L 25/075; H10K 59/38

(52) U.S. Cl. CPC C09K 11/025; C08K 9/04; C09K 11/0883; C09K 11/883; H01L 25/0753; H10K 59/38; B82Y 20/00

(57) ABSTRACT

A quantum dot, a quantum dot composite, a composition for preparing a quantum dot composite, a display panel including the quantum dot composite, and an electronic device including the display panel, wherein the quantum dot includes a core including a semiconductor nanocrystal including indium and phosphorus, a shell disposed on the core and including a semiconductor nanocrystal, and a compound represented by Chemical Formula 1 and a compound represented by Chemical Formula 2, both of which are present on the surface of the shell:

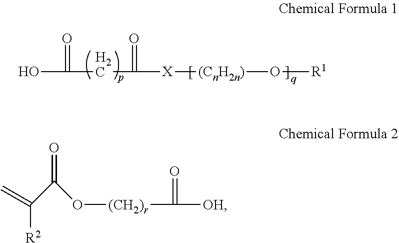

### CROSS-REFERENCE TO RELATED APPLICATION

This application claims priority under 35 U.S.C. § 119 to Korean Patent Application No. 10-2022-0122643 filed in the Korean Intellectual Property Office on Sep. 27, 2022, the content of which is herein incorporated by reference in its entirety.

### BACKGROUND

### 1. Field of the Invention

A quantum dot, a composition for producing a quantum dot composite, a quantum dot composite, and a display panel are disclosed.

### 2. Description of the Related Art

Quantum dots are nano-sized semiconductor nanocrystal materials, where changes to their size and/or composition can control their optical properties, such as, luminous properties. The luminous properties of quantum dots may be applied to electronic device, including display devices. When applied in devices, quantum dots may be applied in the form of a composite. There remains a need for quantum dots and quantum dot composites that are environmentally friendly and capable of exhibiting improved physical properties when applied to electronic devices.

### SUMMARY OF THE INVENTION

A quantum dot according to an embodiment includes a core including a semiconductor nanocrystal including indium (In) and phosphorus (P), a shell disposed on the core and including semiconductor nanocrystals, and a compound represented by Chemical Formula 1 and a compound represented by Chemical Formula 2, both of which are present on the surface of the shell:

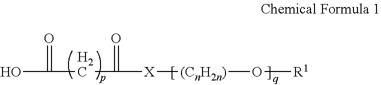

wherein, in Chemical Formula 1,
X is O or NR^{a}, wherein R^{a} is hydrogen or a C1 to C10 alkyl group,
R¹ is hydrogen, a substituted or unsubstituted C1 to C20 alkyl group, a substituted or unsubstituted C2 to C20 alkenyl group, a substituted or unsubstituted C3 to C20 cycloalkyl group, or a substituted or unsubstituted C1 to C20 alkoxy group, and p, q, and n are each independently an integer from 1 to 20;

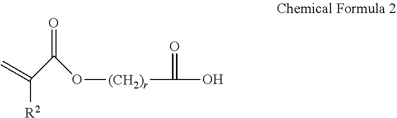

wherein, in Chemical Formula 2,
R² is hydrogen or a substituted or unsubstituted C1 to C20 alkyl group, and
r is an integer from 1 to 10.

In an aspect, in Chemical Formula 1, X is O or NH, R¹ is hydrogen, or a substituted or unsubstituted C1 to C5 alkyl group, p and n are each independently one of integers from 1 to 5, and q is one of integers from 2 to 10.

In another aspect, in Chemical Formula 2, R² is hydrogen or a substituted or unsubstituted C1 to C10 alkyl group, and r is an integer from 2 to 10.

In still another aspect, in Chemical Formula 1, X is O, R¹ is hydrogen, p and n are each independently an integer from 1 to 3, and q is an integer from 5 to 10.

In still another aspect, in Chemical Formula 2, R² is hydrogen, and r is an integer from 2 to 5.

In still another aspect, in the quantum dot, the compound represented by Chemical Formula 1 and the compound represented by Chemical Formula 2 are included in a mole ratio of about 1:0.5 to about 1:3.

In still another aspect, the compound represented by Chemical Formula 1 and the compound represented by Chemical Formula 2, the quantum dot further includes a compound represented by RCOOH, RNH₂, R₂NH, R₃N, RSH, RH₂PO, R₂HPO, R₃PO, RH₂P, R₂HP, R₃P, ROH, RCOOR′, RPO(OH)₂, or R₂POOH, (wherein R and R′ each independently include a (e.g., C1 to C40 or C3 to C35 or C8 to C24) substituted or unsubstituted aliphatic hydrocarbon group (e.g., alkyl group, alkenyl group, alkynyl group), a substituted or unsubstituted (e.g., C3 to C30) alicyclic hydrocarbon group (e.g., cyclopropyl group, cyclobutyl group, cyclopentyl group, cyclohexyl group, cycloheptyl group, cyclooctyl group, cyclononyl group, etc.), or a substituted or unsubstituted (e.g., C6 to C40 or C6 to C30) aromatic hydrocarbon group (e.g., aryl group, etc.), or a combination thereof), or a combination thereof.

In still another aspect, the quantum dot has a peak emission wavelength of about 500 nanometers to about 550 nanometers and does not include cadmium.

In still another aspect, the semiconductor nanocrystal included in the shell includes zinc (Zn) and selenium (Se).

In still another aspect, the semiconductor nanocrystal included in the shell further includes sulfur (S).

In still another aspect, the shell includes a first semiconductor nanocrystal shell disposed on the core and including zinc and selenium, and a second semiconductor nanocrystal shell disposed on the first semiconductor nanocrystal shell and including zinc and sulfur.

In still another aspect, the quantum dot has a ratio of a weight of zinc to a weight of indium of greater than or equal to about 10:1 and less than or equal to about 30:1, and a ratio of a weight of selenium to a weight of indium of greater than or equal to about 2.9:1 and less than or equal to about 20:1.

In still another aspect, a composition for producing a quantum dot composite includes the quantum dot and at least one of a dispersant and a polymerizable monomer including a carbon-carbon unsaturated bond.

In still another aspect, the composition may further include a thiol compound having at least one thiol group at a terminal end, metal oxide particulates, or a combination thereof.

In still another aspect, the dispersant is an organic compound including a carboxyl group, and may include a combination of monomers including a first monomer having a carboxyl group and a carbon-carbon double bond, a second monomer having a carbon-carbon double bond and a hydrophobic moiety and not including a carboxyl group, and optionally a third monomer having a carbon-carbon double bond and a hydrophilic moiety, and not including a carboxyl group, or a copolymer thereof; a polymer containing multiple aromatic rings having a carboxyl group and having a skeletal structure in which two aromatic rings in the main chain are bound to quaternary carbon atoms that are constituent atoms of other cyclic moieties; or a combination thereof.

In still another aspect, the metal oxide fine particulates include TiO₂, SiO₂, BaTiO₃, Ba₂TiO₄, ZnO, or a combination thereof.

In still another aspect, an amount of the quantum dot in the composition is about 1 weight percent to about 50 weight percent, and an amount of a sum of an amount of the compound represented by Chemical Formula 1 and an amount of the compound represented by Chemical Formula 2 is about 1 weight percent to about 50 weight percent, based on a total weight of the composition.

In still another aspect, a quantum dot composite includes a polymer matrix and a plurality of quantum dots dispersed in the polymer matrix, and is configured to emit green light, wherein the plurality of quantum dots include a semiconductor nanocrystal core including indium and phosphorus, a shell disposed on the core and including a semiconductor nanocrystal, and a compound represented by Chemical Formula 1 and a compound represented by Chemical Formula 2 or a moiety therefrom present on the surface of the shell:

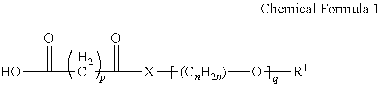

wherein, in Chemical Formula 1,
X is O or NR^{a}, wherein R^{a} is hydrogen or a C1 to C10 alkyl group,
R¹ is hydrogen, a substituted or unsubstituted C1 to C20 alkyl group, a substituted or unsubstituted C2 to C20 alkenyl group, a substituted or unsubstituted C3 to C20 cycloalkyl group, or a substituted or unsubstituted C1 to C20 alkoxy group, and
p, q, and n are each independently an integer from 1 to 20;

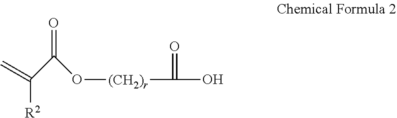

wherein, in Chemical Formula 2,
R² is hydrogen or a substituted or unsubstituted C1 to C20 alkyl group, and
r is an integer from 1 to 10.

The shell including the semiconductor nanocrystal includes zinc and selenium, and the quantum dot is included in an amount of about 1 weight percent to about 50 weight percent based on a total weight of the quantum dot composite.

In still another aspect, the quantum dot composite exhibits greater than or equal to about 90% relative to its initial luminance value when driven for about 500 hours with blue light of about 140,000 nits.

In still another aspect, a display panel includes a quantum dot composite prepared from the composition for producing a quantum dot composite, or the aforementioned quantum dot composite.

In still another aspect, the display panel includes a color conversion layer including a plurality of regions including a color conversion region, and the quantum dot composite is disposed in the color conversion region in the color conversion layer.

In still another aspect, the display panel further includes a light emitting panel including a light emitting source, and the color conversion layer converts an emission spectrum of light emitted from the light emitting panel.

### BRIEF DESCRIPTION OF THE DRAWINGS

The above and other advantages and features of this disclosure will become more apparent by describing in further detail embodiments thereof with reference to the accompanying drawings, in which:

FIG. 1A schematically illustrates an exemplary embodiment of a pattern forming process using a composition for producing a quantum dot composite;

FIG. 1B schematically illustrates an exemplary embodiment of a pattern forming process using an ink composition as a form of a quantum dot composite;

FIG. 2 is a perspective view of an exemplary embodiment of a display panel;

FIG. 3 is a cross-sectional view of an exemplary embodiment of the display panel of FIG. 2;

FIG. 4 is a plan view of an exemplary embodiment of a pixel arrangement of the display panel of FIG. 2;

FIG. 5 is a cross-sectional view of an exemplary embodiment of the display panel of FIG. 4 taken along line IV-IV;

FIG. 6 is a cross-sectional view of an embodiment of a light emitting device;

FIG. 7 is a cross-sectional view of an embodiment of a light emitting device;

FIG. 8 is a cross-sectional view of an embodiment of a light emitting device;

FIG. 9 is a schematic cross-sectional view of an embodiment of a display panel; and

FIG. 10 is a graph illustrating luminance maintenance rates relative to initial luminance (percentage) versus time (hours) in accordance with Evaluation 2.

### DETAILED DESCRIPTION OF THE EMBODIMENTS

A quantum dot composite including quantum dots together with a polymer matrix according to an embodiment may exhibit stable luminescence characteristics without reduction in luminance even when driven for a long time (greater than 500 hours) under a high-luminance light source (about 100,000 nits). Therefore, the quantum dot composite according to an embodiment may be advantageously applied to achieve high luminance, high color purity, and high reliability in various display devices, in particular, devices that implement images such as virtual reality (VR) and augmented reality (AR) that require high luminance, display devices such as watches and televisions.

Advantages and characteristics of this disclosure, and a method for achieving the same, will become evident referring to the following embodiments together with the drawings attached hereto. However, the embodiments should not be construed as being limited to the embodiments set forth herein. If not defined otherwise, all terms (including technical and scientific terms) in the specification may be defined as commonly understood by one skilled in the art. The terms defined in a generally used dictionary may not be interpreted ideally or exaggeratedly unless clearly defined. In addition, unless explicitly described to the contrary, the word “comprise” and variations such as “comprises” or “comprising,” will be understood to imply the inclusion of stated elements but not the exclusion of any other elements.

In the drawings, the thickness of layers, films, panels, regions, etc., are exaggerated for clarity. Like reference numerals designate like elements throughout the specification.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise.

“Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded Thus, the regions illustrated in the figures are schematic in nature and their shapes are not intended to illustrate the precise shape of a region and are not intended to limit the scope of the present claims.

Hereinafter, as used herein, when a definition is not otherwise provided, “substituted” refers to replacement of hydrogen of a compound by a substituent selected from a C1 to C30 alkyl group, a C2 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation, a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

In addition, when a definition is not otherwise provided, “hetero” means including 1 to 3 heteroatoms selected from N, O, S, Si, or P.

As used herein, “alkylene group” is a linear or branched saturated aliphatic hydrocarbon group that optionally includes at least one substituent and has two or more valences. As used herein, “arylene group” may be a functional group that optionally includes at least one substituent, and having two or more valences formed by removal of at least two hydrogens in at least one aromatic ring.

In addition, “aliphatic group” refers to a saturated or unsaturated linear or branched C1 to C30 group consisting of carbon and hydrogen, and “aromatic organic group” includes a C6 to C30 aryl group or a C2 to C30 heteroaryl group, and “alicyclic group” refers to a saturated or unsaturated C3 to C30 cyclic group consisting of carbon and hydrogen.

As used herein, the term “(meth)acrylate” refers to acrylate and/or methacrylate.

As used herein, “dispersion” refers to dispersion wherein a dispersed phase is a solid and a continuous phase includes a liquid. The “dispersion” may include a colloidal dispersion wherein the dispersed phase has a dimension of greater than or equal to about 1 nanometer (nm), for example, greater than or equal to about 2 nm, greater than or equal to about 3 nm, or greater than or equal to about 4 nm and several micrometers (μm) or less, (e.g., about 2 μm or less or about 1 μm or less).

Herein, the term “quantum dot” refer to a nanostructure that exhibits quantum confinement or exciton confinement, such as semiconductor-based nanocrystals (particles), for example, luminescent nanostructure (e.g., capable of emitting light by energy excitation). As used herein, the term “quantum dot” are not limited in shapes thereof, unless otherwise defined.

Here, “a dimension (e.g., size, diameter, thickness, etc.)” may be an average dimension (e.g., size, diameter, thickness, etc.). Here, the “average” may be mean or median. The dimension may be a value obtained by electron microscopic analysis. The dimension may be a value calculated in consideration of the composition and optical properties (e.g., UV absorption wavelength) of the quantum dot.

Herein, “quantum efficiency (or quantum yield)” may be measured in a solution state or in a solid state (in a composite). In an embodiment, quantum efficiency (or quantum yield) is the ratio of photons emitted to photons absorbed by the nanostructure or population thereof. In an embodiment, quantum efficiency may be measured by any method. For example, for fluorescence quantum yield or efficiency, there may be two methods: an absolute method and a relative method. In the absolute method, quantum efficiency is obtained by detecting the fluorescence of all samples through an integrating sphere. In the relative method, the quantum efficiency of the unknown sample is calculated by comparing the fluorescence intensity of a standard dye (standard sample) with the fluorescence intensity of the unknown sample. Coumarin 153, Coumarin 545, Rhodamine 101 inner salt, Anthracene and Rhodamine 6G may be used as standard dyes according to their photoluminescence (PL) wavelengths, but the present disclosure is not limited thereto.

The quantum efficiency (or quantum yield) may be easily and reproducibly determined using commercially available equipment from Hitachi or Hamamatsu, etc. and referring to manuals provided by, for example, respective equipment manufacturers.

The full width at half maximum (FWHM) and maximum emission (PL: photoluminescence) peak wavelength may be measured, for example, by an emission spectrum obtained by a spectrophotometer such as a fluorescence spectrophotometer or the like

Herein, the description that does not include cadmium (or other toxic heavy metals or given elements) means that a concentration of cadmium (or the corresponding heavy metals or given elements) is less than or equal to about 100 parts per million (ppm), less than or equal to about 50 ppm, less than or equal to about 10 ppm, or near zero. In an embodiment, substantially no cadmium is present, or, if present, is present in an amount below the detection limit of a given detection means or at an impurity level.

The semiconductor nanocrystals, also called “quantum dot”, are crystalline semiconductor materials with nanoscale particle sizes. The quantum dot has a large surface area per unit volume, exhibits a quantum confinement effect, and may exhibit properties different from those of bulk materials having the same composition. The quantum dot absorbs light from an excitation source to be excited, and emits energy corresponding to its bandgap energies.

The quantum dot may be applied as light emitting materials in display devices. For example, the quantum dot composite including a plurality of quantum dots dispersed in a polymer matrix or the like may be used as a light conversion layer (e.g., a color conversion layer) that converts a light (e.g., blue light) of a desired wavelength, for example, green light or red light from a light source (e.g., a backlight unit (BLU)) in a display device. That is, unlike the conventional absorption type color filter, a patterned film including the quantum dot composite may be used as an emission type color filter. Since the emission type color filter is disposed in front of a display device, for example, when excitation light, which has linearity while passing through the liquid crystal layer, reaches the emission type color filter, it is scattered in all directions to realize a wider viewing angle, and light loss due to the absorption type color filter may be avoided.

In order to form a color conversion layer with quantum dots, for example, a pixel having a desired pattern should be formed by preparing a photoresist (PR) composition or ink composition including quantum dots, and applying it to a patterning process or a printing process. In order to prepare such a PR composition or ink composition, quantum dots should be well mixed with a monomer or a binder included in the PR composition or ink composition, and for this purpose, the following two methods may be used.

The first method is a method of applying an amphoteric solvent that can be mixed well with both the quantum dots and the binder. A composition, for example, a PR composition, can be prepared by uniformly dispersing the quantum dots and the binder using an amphoteric solvent.

Another method is by substituting a ligand on the surface of the quantum dots. In the case of preparing quantum dots by a wet process that is commonly used in preparing quantum dots, compounds for forming an organic solvent used in the preparation of quantum dots or an organic compound added in order to control sizes of the quantum dots or passivate the surface defects during the quantum dot preparing process may be bound to the surface of the quantum dots. In this way, by substituting the organic compound bound to the surface of the quantum dots, that is, the so-called ligand material with a hydrophilic material, the method may make the substituted quantum dots well dispersed in the PR composition or ink composition.

However, the first method has a problem that the degree of dispersion of the quantum dots may vary depending on the type or characteristics of the solvent, and there are not many types of amphoteric solvents applicable for industrial purposes. In addition, when the above solvent is used, dispersibility is not sufficient and a dispersant should be added to the composition to ensure through dispersion, leading to a limited viscosity range of the composition. In addition, the method of using an amphoteric solvent is mainly applicable to the PR composition, and may be applied to an ink composition, but it is not suitable for application as a color conversion layer.

For the second method, the properties of the quantum dots may vary widely depending on how the ligand substitution is performed, and the second method may be applied to a solvent-free ink composition applied without a solvent and also to a PR composition. Such a ligand substitution method has been approached as one of the methods for well dispersing quantum dots in PR or ink composition. The ability of a composite including ligand-substituted quantum dots to exhibit stable luminescence characteristics without a decrease in luminance when driven for a long time under a high-luminance light source and the potential effects of substituting the ligand to bring about the above effect require research.

Meanwhile, a color conversion layer using quantum dots may be applied to various display devices. Examples of such a display device include various devices such as a watch, a mobile phone, a TV, augmented reality (AR), and virtual reality (VR). Among these devices, a device including a liquid crystal display (LCD) or an organic light emitting diode (OLED) as a light source may have sufficient white luminance from a blue luminance of about 1,000 nits to about 3,000 nits and a sufficient life-span of greater than or equal to about 10,000 hours (hr). However, in the case of mini LED, micro LED (μLED), etc., a blue light source of hundreds of thousands of nits is required, and in order to be used as a color conversion layer for such a high-luminance light source, stability of quantum dots is important. Among the quantum dots developed so far, there have been no reports of quantum dots operating at hundreds of thousands of nits for 500 hours or more. For example, in the case of previously developed green quantum dots, when applied to a light source with an initial luminance of about 100,000 nits, luminance may significantly decrease at the same time as driving and thus the luminance decreases by about 30% or more before 100 hours, and the luminance decreases by about 50% after 200 hours.

The present inventors have worked to solve the above problems, and to prepare a color conversion layer including a quantum dot composite that can be stably driven for a long period without a decrease in luminance even when applied to a high-luminance light source, and as a result, it has been found that when the quantum dot includes two specific types of compounds on its surface, a quantum dot composite including such quantum dots can solve the above problem.

Specifically, the quantum dot according to an embodiment includes a core including a semiconductor nanocrystal including indium and phosphorus, a shell disposed on the core and including semiconductor nanocrystals, and a compound represented by Chemical Formula 1 and a compound represented by Chemical Formula 2, both of which are present on the surface of the shell:

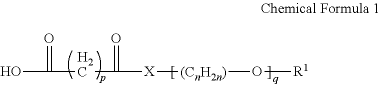

wherein, in Chemical Formula 1,
X is O or NR^{a}, wherein R^{a} is hydrogen or a C1 to C10 alkyl group,
R¹ is hydrogen, a substituted or unsubstituted C1 to C20 alkyl group, a substituted or unsubstituted C2 to C20 alkenyl group, a substituted or unsubstituted C3 to C20 cycloalkyl group, or a substituted or unsubstituted C1 to C20 alkoxy group, and
p, q, and n are each independently an integer from 1 to 20;

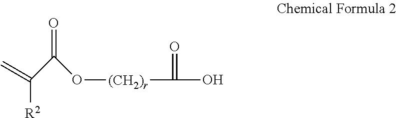

wherein, in Chemical Formula 2,
R² is hydrogen or a substituted or unsubstituted C1 to C20 alkyl group, and
r is an integer from 1 to 10.

As described above, when the quantum dot is prepared using a wet process, organic compounds are bound to the surface of the prepared quantum dot, and these organic compounds are compounds with a hydrophobic moiety that allows the quantum dot to be well dispersed in organic solvents, especially hydrophobic organic solvents. Examples of such compounds may include saturated or unsaturated fatty acids commonly used in the preparation of quantum dots, such as organic acids having a linear saturated or unsaturated aliphatic hydrocarbon group with a large number of carbon atoms and a carboxyl group such as oleic acid, palmitic acid, etc., or organic amines having a linear saturated or unsaturated aliphatic hydrocarbon group together with an amino group instead of a carboxyl group, and many other types of compounds. A quantum dot, which mainly includes these organic compounds on the surface, are not well dispersed in hydrophilic media such as an ink composition or PR composition.

The quantum dot according to an embodiment include, a compound represented by Chemical Formula 1, that is, a compound having a carboxyl group at one terminal end, a hydrophilic group such as a hydroxy group or an alkoxy group at the other terminal end, and an alkylenoxy group along with an ester (if X is O) bond or amide (if X is NR^{a}) bond as a linking group between these two terminal ends to have overall hydrophilic property on the surface, and additionally, a compound represented by Chemical Formula 2, that is, a compound having a carboxyl group at one terminal end and an (alkyl)acrylate group at the other terminal end, and an alkylene linkage group between both terminal ends, instead of or together with the organic compounds having the above hydrophobic moiety.

Although not intended to be bound by a specific theory, the compound represented by Chemical Formula 1 has a carboxyl group at one terminal end, so that it can bind well to the surface of inorganic quantum dot, and has a hydrophilic group at the other terminal end, so that it can play a role in ensuring that quantum dots are well dispersed in hydrophilic compositions such as an ink composition or a PR composition. In addition, the compound represented by Chemical Formula 2 can also bind well to the surface of quantum dot through the carboxyl group present at one terminal end, and can perform a photopolymerization reaction with a photopolymerizable compound containing a carbon-carbon double bond included in the ink composition or PR composition through the carbon-carbon double bond present at the other terminal end. Thereby, the ink composition or PR composition including the quantum dot according to an embodiment can have the quantum dots uniformly dispersed therein, and upon exposure thereof, the compound represented by Chemical Formula 2 bound to the surface of the quantum dots is photopolymerized with the photopolymerizable compound in the ink composition or the PR composition, and thereby the quantum dots in the polymer matrix of the quantum dot composite produced therefrom may be more stably bound and well dispersed. As a result, as demonstrated through later examples, a quantum dot composite produced from the quantum dot including the compound represented by Chemical Formula 1 and the compound represented by Chemical Formula 2 on its surface according to an embodiment exhibits a remarkable effect of maintaining greater than or equal to about 90%, for example, greater than or equal to about 95% relative to the initial luminance even when driven for 500 hours using a light source of 100,000 nits or more. In contrast, a quantum dot composite including a quantum dot that does not include any of the compound represented by Chemical Formula 1 or the compound represented by Chemical Formula 2 exhibits a decrease in luminance of greater than or equal to about 30% relative to the initial luminance occurs within 100 hours, and a significant decrease in luminance of greater than or equal to about 50% relative to the initial luminance after 200 hours.

In conclusion, the quantum dot according to an embodiment has an initial luminance rate of greater than or equal to about 90%, for example, greater than or equal to about 91%, greater than or equal to about 92%, greater than or equal to about 93%, greater than or equal to about 94%, greater than or equal to about 95%, greater than or equal to about 96%, or greater than or equal to about 97%, when the quantum dot composite including the quantum dot is driven for a long time under high luminance conditions, thereby ensuring high reliability of a display device including the quantum dot according to an embodiment. Therefore, the quantum dot according to an embodiment may be advantageously applied to various display devices that require high luminance of tens of thousands of nits or more.

In an example embodiment, in Chemical Formula 1, X may be O or NH, R¹ may be hydrogen, or a substituted or unsubstituted C1 to C5 alkyl group, p and n may each independently be one of integers from 1 to 5, and q may be an integer from 2 to 10. For example, in Chemical Formula 1, X may be O, R¹ may be hydrogen, p and n may each independently be an integer from 1 to 3, for example, p and n may each be 2, and q may be an integer from 5 to 10, for example, q may be an integer of 7 to 10, for example, q may be 7, but are not limited thereto.

Additionally, in Chemical Formula 2, R² may be hydrogen or a substituted or unsubstituted C1 to C10 alkyl group, and r may be an integer from 2 to 10. For example, R² in Chemical Formula 2 may be hydrogen, and r may be an integer from 2 to 5, for example, an integer of 2, 3, 4, or 5, but not limited thereto.

In an embodiment, the compound represented by Chemical Formula 1 may be represented by Chemical Formula 1-1, and the compound represented by Chemical Formula 2 may be represented by Chemical Formula 2-1, but is not limited to these compounds.

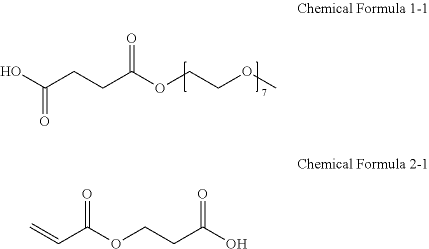

The compound represented by Chemical Formula 1 and the compound represented by Chemical Formula 2 may be present on the surface of the quantum dot in a mole ratio of about 1:0.5 to about 1:3. When the compound represented by Chemical Formula 1 and the compound represented by Chemical Formula 2 are included in the above ratio, the quantum dots surface-modified with these compounds can be uniformly well dispersed in the ink composition, and in addition, the quantum dot composite including these quantum dots can provide high reliability under high luminance conditions.

As can be seen from the examples described later, for the preparation of quantum dots according to an embodiment, when quantum dots are reacted by adding quantum dots to a solution in which the compound represented by Chemical Formula 1 and the compound represented by Chemical Formula 2 exist at a mole ratio of 1:3.5, the surface modification of the quantum dots by these compounds does not occur well. That is, as described above, when quantum dots including organic compounds on their surface are added to a solution in which the compounds exist in the mole ratio through a wet process, the compounds are not well bound to the surface of the quantum dots. Whether the compounds are well bound to the surface of the quantum dots can be determined by adding the compounds to a solvent including the quantum dots to be surface modified and reacting for a certain period of time, then the reacted quantum dots are added to a solvent such as cyclohexane, that is, a solvent in which the compounds do not dissolve well, followed by centrifugation, thereby separating the quantum dots to which the compounds are bound. At this time, if there are few or small amounts of the quantum dots centrifuged, it can be considered that the compounds are not well bound to the surface of the quantum dots. When the compound represented by Chemical Formula 1 and the compound represented by Chemical Formula 2 at a mole ratio of about 1:3.5 are added to the solvent in which the quantum dots are dispersed to react with them, (unlike the case where the compounds are added at a mole ratio of about 1:2.5 and reacted with the quantum dots), the amount of centrifuged quantum dots is small. As a result, when the mole ratio of the two compounds exceeds about 1:3, for example, is 1:3.5, it is difficult for the two compounds to be bound to the surface of the quantum dots.

On the other hand, when the mole ratio of the compound represented by Chemical Formula 1 and the compound represented by Chemical Formula 2 is less than about 1:0.5, the amount of the compound represented by Chemical Formula 2 is too small to produce a synergistic effect due to the combination of the two compounds, that is, a high luminance maintenance rate cannot be obtained when driving for a long time under high luminance conditions. For example, as can be seen from Comparative Example 1 described later, when the compound represented by Chemical Formula 1 is bound alone to the surface of quantum dots, that is, when the mole ratio of the compound represented by Chemical Formula 1 and the compound represented by Chemical Formula 2 on the surface of quantum dots is 1:0, the luminance after driving the quantum dot composite including these quantum dots with a blue LED of about 140,000 nits for about 500 hours is only about 75% of the initial luminance. On the other hand, when the mole ratio described above, that is, the mole ratio of the compound represented by Chemical Formula 1 and the compound represented by Chemical Formula 2 is 1:0.5 to 1:3, a quantum dot composite including quantum dots including these two compounds on the surface of the quantum dot exhibits a high luminance maintenance rate of greater than or equal to about 95% relative to the initial luminance under the same conditions.

Meanwhile, the quantum dot according to an embodiment may further include, in addition to the compound represented by Chemical Formula 1 and the compound represented by Chemical Formula 2, an additional organic compound may be present on the surface of the quantum dot manufactured by a wet preparing method. The additional organic compound may be organic compounds that have a functional group that can bind to the surface of quantum dot, such as a carboxyl group, an amine group, a thiol group, a phosphate group, a hydroxy group, or an ester group, at one terminal end, and have a hydrophobic moiety at the other terminal end so that the quantum dot can be well dispersed in the hydrophobic organic solvent used to produce quantum dot. For example, the organic compound may include RCOOH, RNH₂, R₂NH, R₃N, RSH, RH₂PO, R₂HPO, R₃PO, RH₂P, R₂HP, R₃P, ROH, RCOOR′, RPO (OH)₂, R₂POOH {wherein R and R′ are each independently (e.g., C1 to C40 or C3 to C35 or C8 to C24) substituted or unsubstituted aliphatic hydrocarbon group (e.g., alkyl group, alkenyl group, alkynyl group), a substituted or unsubstituted (e.g., C3 to C30) alicyclic hydrocarbon group (e.g., cyclopropyl group, cyclobutyl group, cyclopentyl group, cyclohexyl group, cycloheptyl group, cyclooctyl group, cyclononyl group, etc.), or a substituted or unsubstituted (e.g., C6 to C40 or C6 to C30) aromatic hydrocarbon group (e.g., aryl group, etc.), or a combination thereof}.

Specific examples of the organic compound include a thiol compound such as methane thiol, ethane thiol, propane thiol, butane thiol, pentane thiol, hexane thiol, octane thiol, dodecane thiol, hexadecane thiol, octadecane thiol, or benzyl thiol; an amine compound such as methane amine, ethane amine, propane amine, butyl amine, pentyl amine, hexyl amine, octyl amine, dodecyl amine, hexadecyl amine, octadecyl amine, dimethyl amine, diethyl amine, or dipropyl amine; an carboxyl group-containing compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, palmitic acid, or benzoic acid; an aliphatic phosphine compound such as substituted or unsubstituted methyl phosphine (e.g., trimethyl phosphine, methyldiphenyl phosphine, etc.), substituted or unsubstituted ethyl phosphine (e.g., triethyl phosphine, ethyldiphenyl phosphine, etc.), substituted or unsubstituted propyl phosphine, substituted or unsubstituted butyl phosphine, substituted or unsubstituted pentyl phosphine, or substituted or unsubstituted octylphosphine (e.g., trioctylphosphine (TOP)); a phosphine oxide compound such as substituted or unsubstituted methyl phosphine oxide (e.g., trimethyl phosphine oxide, methyldiphenyl phosphineoxide, etc.), substituted or unsubstituted ethyl phosphine oxide (e.g., triethyl phosphine oxide, ethyldiphenyl phosphineoxide, etc.), substituted or unsubstituted propyl phosphine oxide, substituted or unsubstituted butyl phosphine oxide, or substituted or unsubstituted octylphosphineoxide (e.g., trioctylphosphineoxide (TOPO), and the like; an aromatic phosphine compound such as diphenyl phosphine or triphenyl phosphine, or an oxide compound thereof; a phosphonic acid, and the like, but are not limited thereto.

The additional organic compounds that may be present on the surface of the quantum dot may be included in an amount of less than or equal to about 30 weight percent (wt %) based on a total weight of the total organic compounds present on the surface of the quantum dot according to an embodiment. For example, the additional organic compound may be included in an amount of less than or equal to about 25 wt %, less than or equal to about 20 wt %, or less than or equal to about 15 wt %, less than or equal to about 10 wt %, less than or equal to about 5 wt % based on a total weight of compounds that may be present on the surface of the quantum dot, or may not be included at all.

The quantum dot according to an embodiment may be a quantum dot that emits green light with a light emitting peak from about 500 nm and about 550 nm. In this case, the emission peak of the quantum dot may exist at greater than or equal to about 510 nm, greater than or equal to about 520 nm, greater than or equal to about 530 nm, or greater than or equal to about 535 nm and less than or equal to about 545 nm, less than or equal to about 540 nm, or less than or equal to about 535 nm.

In the case of a quantum dot including semiconductor nanocrystals including indium and phosphorus in the core, the quantum dot can emit green light or red light depending on their size or composition. In this case, the size of the quantum dot emitting red light may be larger than the size of the quantum dot emitting green light, and therefore, the quantum dot including the core including the semiconductor nanocrystal including indium and phosphorus and emitting red light may be more physically and chemically stable than the quantum dot emitting green light. Therefore, a quantum dot including indium and phosphorus, which require improving the stability of quantum dot by modifying their surfaces with the compound represented by Chemical Formula 1 and the compound represented by Chemical Formula 2, may be a quantum dot emitting green light.

Meanwhile, in the quantum dot according to an embodiment, the semiconductor nanocrystal included in the shell disposed on the core may include zinc and selenium. Additionally, the semiconductor nanocrystal included in the shell may further include sulfur.

When the semiconductor nanocrystal included in the shell further includes sulfur, the shell may further include a first semiconductor nanocrystal layer disposed on the core and including zinc and selenium, and a second semiconductor nanocrystal layer disposed on the first semiconductor nanocrystal layer and including zinc and sulfur. At this time, the first semiconductor nanocrystal layer may or may not include ZnSeS. The first semiconductor nanocrystal layer may be disposed directly on the core.

The second semiconductor nanocrystal layer may include ZnS. The second semiconductor nanocrystal layer may not include selenium. The second semiconductor nanocrystal layer may be disposed directly on the first semiconductor nanocrystal layer. The second semiconductor nanocrystal layer may be present at the outermost layer of the quantum dot.

In an embodiment, the semiconductor nanocrystal included in the core may or may not further include zinc.

In an embodiment, the semiconductor nanocrystal included in the core may be InP or InZnP. An (average) size of the core may be greater than or equal to about 1 nm, greater than or equal to about 1.5 nm, greater than or equal to about 2 nm, greater than or equal to about 3 nm, or greater than or equal to about 3.3 nm. For example, a size of the core may be less than or equal to about 5 nm, less than or equal to about 4 nm, or less than or equal to about 3.8 nm.

In an embodiment, a shell thickness of the quantum dot may be greater than or equal to about 1.5 nm, greater than or equal to about 1.6 nm, greater than or equal to about 1.7 nm, greater than or equal to about 1.8 nm, greater than or equal to about 1.9 nm, or greater than or equal to about 2 nm. For example, the thickness of the semiconductor nanocrystal shell may be less than or equal to about 2.5 nm, less than or equal to about 2.4 nm, less than or equal to about 2.3 nm, less than or equal to about 2.2 nm, or less than or equal to about 2.1 nm.

In an embodiment, the first semiconductor nanocrystal layer of the shell may have a thickness of about 3 monolayers (ML) or more, for example, about 3.5 ML or more, about 3.6 ML or more, about 3.7 ML or more, about 3.8 ML or more, about 3.9 ML or more, about 4 ML or more, about 4.1 ML or more, about 4.2 ML or more, about 4.3 ML or more, or about 4.4 ML or more. The first semiconductor nanocrystal layer may have a thickness of about 7 ML or less, for example, about 6 ML or less, or about 5 ML or less. In an embodiment, the first semiconductor nanocrystal layer may have a thickness of greater than or equal to about 0.9 nm, greater than or equal to about 1 nm, greater than or equal to about 1.1 nm, greater than or equal to about 1.2 nm, greater than or equal to about 1.3 nm, greater than or equal to about 1.4 nm, greater than or equal to about 1.43 nm, or greater than or equal to about 1.45 nm. In an example embodiment, the first semiconductor nanocrystal layer may have a thickness of less than or equal to about 1.8 nm, less than or equal to about 1.75 nm, less than or equal to about 1.7 nm, less than or equal to about 1.6 nm, less than or equal to about 1.55 nm, or less than or equal to about 1.51 nm.

A (average) thickness of the second semiconductor nanocrystal layer may be less than or equal to about 0.65 nm, less than or equal to about 0.64 nm, less than or equal to about 0.63 nm, less than or equal to about 0.62 nm, less than or equal to about 0.61 nm, less than or equal to about 0.6 nm, or less than or equal to about 0.59 nm. The thickness of the second semiconductor nanocrystal layer may be greater than or equal to about 0.4 nm, greater than or equal to about 0.45 nm, greater than or equal to about 0.5 nm, greater than or equal to about 0.51 nm, greater than or equal to about 0.52 nm, greater than or equal to about 0.53 nm, or greater than or equal to about 0.54 nm.

The quantum dot may refer to one particle (single entity) or a plurality of particles, and may not contain harmful heavy metals (e.g., cadmium, lead, mercury, or a combination thereof).

In the quantum dot of an embodiment, a ratio (Zn/In) of a weight of zinc to a weight of indium may be greater than or equal to about 10:1 and less than or equal to about 30:1, for example, greater than or equal to about 11:1 and less than or equal to about 29:1, greater than or equal to about 11.5:1 and less than or equal to about 27:1, greater than or equal to about 11.7:1 and less than or equal to about 26:1, but is not limited thereto. For example, the ratio (Zn/In) of a weight of zinc to a weight of indium may be greater than or equal to about 11.3:1, greater than or equal to about 11.5:1, greater than or equal to about 11.7:1, greater than or equal to about 11.75:1, greater than or equal to about 12:1, greater than or equal to about 13:1, greater than or equal to about 13.5:1, greater than or equal to about 14:1, greater than or equal to about 15:1, greater than or equal to about 16:1, greater than or equal to about 17:1, greater than or equal to about 18:1, greater than or equal to about 19:1, greater than or equal to about 20:1, greater than or equal to about 21:1, greater than or equal to about 22:1, greater than or equal to about 23:1, greater than or equal to about 24:1, or greater than or equal to about 25:1, and less than or equal to about 30:1, less than or equal to about 29:1, less than or equal to about 28:1, less than or equal to about 27.5:1, less than or equal to about 27:1, less than or equal to about 26.5:1, less than or equal to about 26:1, less than or equal to about 25.8:1, less than or equal to about 25.7:1, less than or equal to about 25.5:1, less than or equal to about 25:1, less than or equal to about 24:1, less than or equal to about 23:1, less than or equal to about 22:1, less than or equal to about 21:1, less than or equal to about 20:1, less than or equal to about 19:1, less than or equal to about 18:1, less than or equal to about 17:1, less than or equal to about 16:1, less than or equal to about 15.5:1, less than or equal to about 15:1, less than or equal to about 14:1, less than or equal to about 13.5:1, less than or equal to about 13:1, less than or equal to about 12.5:1, less than or equal to about 12:1, less than or equal to about 11.75:1, less than or equal to about 11.5:1, less than or equal to about 11:1, or less than or equal to about 10.5:1, but is not limited thereto.

In the quantum dot according to an embodiment, a ratio of a weight of selenium to a weight of indium may be greater than or equal to about 2.9:1 and less than or equal to about 20:1, for example, greater than or equal to about 3:1, greater than or equal to about 4:1, greater than or equal to about 5:1, greater than or equal to about 6:1, greater than or equal to about 7:1, greater than or equal to about 8:1, greater than or equal to about 9:1, greater than or equal to about 10:1, greater than or equal to about 11:1, greater than or equal to about 12, greater than or equal to about 13:1, greater than or equal to about 14:1, greater than or equal to about 15:1, greater than or equal to about 16, greater than or equal to about 17:1, greater than or equal to about 18, or greater than or equal to about 19 and less than or equal to about, 20:1, less than or equal to about 19:1, less than or equal to about 18:1, less than or equal to about 17:1, less than or equal to about 16:1, less than or equal to about 15:1, less than or equal to about 14:1, less than or equal to about 13:1, less than or equal to about 12:1, less than or equal to about 11:1, less than or equal to about 10.5:1, less than or equal to about 10:1, less than or equal to about 9:1, less than or equal to about 8:1, less than or equal to about 7:1, less than or equal to about 6:1, less than or equal to about 5:1, less than or equal to about 4:1, or less than or equal to about 3:1, but is not limited thereto.

In the quantum dot according to an embodiment, a ratio (S/In) of a weight of sulfur to a weight of indium may be greater than or equal to about 1:1 and less than or equal to about 10:1, for example, greater than or equal to about 1.2:1 and less than or equal to about 9:1, greater than or equal to about 1.25:1 and less than or equal to about 8.7:1, but is not limited thereto. For example, the ratio may be greater than or equal to about 1.2:1, greater than or equal to about 1.28:1, greater than or equal to about 1.3, greater than or equal to about 1.5:1, greater than or equal to about 2:1, greater than or equal to about 3:1, greater than or equal to about 4:1, greater than or equal to about 5:1, greater than or equal to about 6:1, greater than or equal to about 7:1, greater than or equal to about 8:1, or greater than or equal to about 9:1, and less than or equal to about 10:1, less than or equal to about 9.5:1, less than or equal to about 9:1, less than or equal to about 8.7:1, less than or equal to about 8.5:1, less than or equal to about 8:1, less than or equal to about 7:1, or less than or equal to about 6:1, but is not limited thereto.

In the quantum dot, a mole ratio (In/(S+Se)) of indium to a sum of sulfur and selenium may be greater than or equal to about 0.09:1, greater than or equal to about 0.095:1, greater than or equal to about 0.097:1, or greater than or equal to about 0.0975:1. In the quantum dot, a mole ratio (In/(S+Se)) of indium to the sum of sulfur and selenium may be less than or equal to about 0.12:1, less than or equal to about 0.115:1, less than or equal to about 0.113:1, less than or equal to about 0.111:1, less than or equal to about 0.11:1, or less than or equal to about 0.109:1.

In the quantum dot, the mole ratio of the sum of sulfur and selenium to indium may be greater than or equal to about 8.96:1, greater than or equal to about 9.1:1, greater than or equal to about 9.2:1, greater than or equal to about 9.3:1, greater than or equal to about 9.4:1, greater than or equal to about 9.5:1, greater than or equal to about 9.6:1, greater than or equal to about 9.65:1, greater than or equal to about 9.7:1, greater than or equal to about 9.8:1, greater than or equal to about 9.9:1, greater than or equal to about 10:1, greater than or equal to about 10.1:1, or greater than or equal to about 10.2:1. In the quantum dot, the mole ratio of the sum of sulfur and selenium to indium may be less than or equal to about 10.5:1, less than or equal to about 10.3:1, or less than or equal to about 10.25:1.

A size of the quantum dot according to an embodiment may be greater than or equal to about 7.5 nm, greater than or equal to about 7.6 nm, or greater than or equal to about 7.7 nm. The size of the quantum dot may be less than or equal to about 8 nm, less than or equal to about 7.9 nm, or less than or equal to about 7.8 nm.

The size or average size of the quantum dot may be calculated from an electron microscope analysis image. In an embodiment, the size (or average size) may be a diameter or equivalent diameter (or an average value thereof) determined from electron microscopy image analysis.

The shape of the quantum dot is not particularly limited, and may include, for example, spherical, polyhedral, pyramidal, multipod, or cubic, nanotubes, nanowires, nanofibers, nanosheets, or a combination thereof, but is not limited thereto.

The quantum dot according to an embodiment may have a quantum efficiency of greater than or equal to about 90%, greater than or equal to about 91%, greater than or equal to about 92%, greater than or equal to about 93%, greater than or equal to about 94%, or greater than or equal to about 95% in a solution state or a solid state. In addition, the quantum dot may have a full width at half maximum (FWHM) of less than or equal to about 40 nm, for example, less than or equal to about 39 nm in a solution state or a solid state.

Hereinafter, a method of preparing the quantum dot according to an embodiment is explained.

The quantum dot according to an embodiment are surface-modified so that the compound represented by Chemical Formula 1 and the compound represented by Chemical Formula 2 may be present on the surface of the quantum dot including a core including a semiconductor nanocrystal including indium and phosphorus and a shell disposed on the core and including a semiconductor nanocrystal. Herein, the quantum dot including the core including the semiconductor nanocrystal including indium and phosphorus and the shell disposed on the core and including the semiconductor nanocrystal may be prepared in-situ using a wet process, or commercially available quantum dot as described above may be purchased.

An example of the method of preparing the quantum dot using a wet process is explained as follows.

First, a quantum dot including a core that includes semiconductor nanocrystals including indium and phosphorus is prepared, and the core is reacted with precursors for forming a semiconductor nanocrystal shell including zinc and selenium, and optionally sulfur, in a suitable solvent, together with the prepared core. Alternatively, optionally, in order to form a shell including an additional semiconductor nanocrystal including additional zinc and sulfur, and optionally selenium to the particles in which the semiconductor nanocrystal shell is formed on the semiconductor nanocrystal core by the reaction, a method of further reacting by introducing precursors for forming a semiconductor nanocrystal shell may be performed. In this case, the quantum dot may include a first semiconductor nanocrystal shell including zinc and selenium, and optionally sulfur on the semiconductor nanocrystal core including indium and phosphorus, and a second semiconductor nanocrystal shell including zinc and sulfur, and optionally selenium on the first semiconductor nanocrystal shell. Herein, a sulfur precursor may not be included when the first semiconductor nanocrystal shell is formed, and/or a selenium precursor may not be included when the second semiconductor nanocrystal shell is formed. Accordingly, the quantum dot may include a semiconductor nanocrystal core including indium and phosphorus, a first semiconductor nanocrystal shell disposed on the semiconductor nanocrystal core and including zinc and selenium; and a second semiconductor nanocrystal shell disposed on the first semiconductor nanocrystal shell and including zinc and sulfur.

On the other hand, the semiconductor nanocrystal core including indium and phosphorus is commercially available or may be synthesized by a known method for preparing an indium phosphide-based core. The core of an embodiment may be prepared by a hot injection method in which a solution including metal precursors such as an indium precursor and, optionally, a ligand are heated to a high temperature, for example, about 200° C. or higher, and a phosphorus precursor is injected.

In each reaction step for preparing the quantum dot, the content of the zinc precursor, the selenium precursor, and the sulfur precursor relative to indium and the total used amount of each precursor may be adjusted to satisfy the composition of the quantum dot to be finally prepared. In each step, the desired reaction time may be adjusted to obtain the desired composition and/or structure (e.g., core/multilayer shell structure) in the final quantum dot.

When preparing the quantum dot, if necessary, surfactants in addition to the aforementioned organic compounds may be further included for reaction.

The zinc precursor is not particularly limited, and may be a Zn metal powder, an alkylated Zn compound, a Zn alkoxide, a C2 to C10 Zn carboxylate, a Zn nitrate, a Zn perchlorate, a Zn sulfate, a Zn acetylacetonate, a Zn halide, a Zn cyanide, a Zn hydroxide, a Zn oxide, a Zn peroxide, or a combination thereof.

Examples of precursors for forming the first semiconductor nanocrystal shell may include dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, and the like, but are not limited thereto.

The selenium-containing precursor is not particularly limited, and may be for example, selenium, selenium-trioctylphosphine (Se-TOP), selenium-tributylphosphine (Se-TBP), selenium-triphenylphosphine (Se-TPP), or a combination thereof.

The sulfur-containing precursor is not particularly limited, and may be, for example, a sulfur powder, hexane thiol, octane thiol, decane thiol, dodecane thiol, hexadecane thiol, mercaptopropyl silane, sulfur-trioctylphosphine (S-TOP), sulfur-tributylphosphine (S-TBP), sulfur-triphenylphosphine (S-TPP), sulfur-trioctylamine (S-TOA), trimethylsilyl sulfur, ammonium sulfide, sodium sulfide, or a combination thereof.

The (organic) solvent may include C6 to C22 primary amines such as hexadecylamine; C6 to C22 secondary amines such as dioctylamine; C6 to C40 tertiary amines such as trioctylamine; nitrogen-containing heterocyclic compounds such as pyridine; C6 to C40 aliphatic hydrocarbons (e.g., alkanes, alkenes, alkynes, etc.) such as hexadecane, octadecane, octadecene, and squalane; C6 to C30 aromatic hydrocarbons such as phenyldodecane, phenyltetradecane, and phenyl hexadecane; phosphine substituted with a C6 to C22 alkyl group such as trioctylphosphine; phosphine oxide substituted with a C6 to C22 alkyl group such as trioctylphosphine oxide; C12 to C22 aromatic ethers such as phenyl ether, benzyl ether, and a combination thereof. Types and contents of the solvent may be appropriately selected in consideration of the types of the precursors and the organic ligand.

Meanwhile, if a nonsolvent is added to the final reaction solution in which the quantum dot is prepared, an organic compound, that is, the quantum dot coordinated with a ligand, may be separated (e.g. precipitated). The nonsolvent may be a polar solvent that is miscible with the solvent used in the reaction but cannot disperse the semiconductor nanocrystals. The nonsolvent may be selected depending on the solvent used in the reaction and may be for example, acetone, ethanol, butanol, isopropanol, ethanediol, water, tetrahydrofuran (THF), dimethylsulfoxide (DMSO), diethylether, formaldehyde, acetaldehyde, a solvent having a similar solubility parameter to the foregoing solvents, or a combination thereof.

The quantum dot precipitated by the addition of a nonsolvent may be separated through methods such as centrifugation, precipitation, chromatography, and distillation. The separated quantum dot can be washed using washing solvent as needed. The washing solvent is not particularly limited, and a solvent having a solubility parameter similar to that of the ligand coordinated to the surface of the quantum dot may be used. Examples thereof may include hexane, heptane, octane, chloroform, toluene, benzene, and the like, but are not limited thereto.

In addition, a method for preparing a quantum dot according to an embodiment includes reacting the quantum dots and the two types of compounds together so that the compound represented by Chemical Formula 1 and the compound represented by Chemical Formula 2 are present on the surface of quantum dots prepared by the above method or purchased commercially.

Specifically, after redispersing the quantum dots prepared as above or commercially purchased quantum dots in a solvent in which the compound represented by Chemical Formula 1 and the compound represented by Chemical Formula 2 can be dissolved, it includes adding and reacting the compound represented by Chemical Formula 1 and the compound represented by Chemical Formula 2 to the solution in which the quantum dots are dispersed. In this case, the compound represented by Chemical Formula 1 and the compound represented by Chemical Formula 2 are added together at the same time, or one of the two types of compounds may be added first and reacted, and then the remaining type of compound may be further added and reacted. After the binding reaction of the compound is completed, in order to separate the quantum dots in which both the compound represented by Chemical Formula 1 and the compound represented by Chemical Formula 2 are bound to the surface of the quantum dot, in the same manner as the separation method after preparing the quantum dots, by adding a non-solvent that does not dissolve the compound represented by Chemical Formula 1 and/or the compound represented by Chemical Formula 2, quantum dots according to an embodiment in which the above two types of compounds are bound to their surfaces can be separated by a precipitation method or the like.

The method of preparing the above-described quantum dots, the method of modifying the surface of the quantum dots with organic compounds, etc. are well known to those skilled in the art, and quantum dots according to an embodiment can be easily prepared using this method.

A composition for producing a quantum dot composite according to another embodiment includes the aforementioned quantum dot, and at least one of a polymerizable monomer and a dispersant.

The polymerizable monomer may be a (photo) polymerizable monomer including a carbon-carbon double bond. The dispersant may disperse the quantum dot according to an embodiment. The dispersant may include a carboxyl group (—COOH)-containing compound (monomer or polymer). The composition may optionally further include a (thermal or photo) initiator, and/or (organic) solvent (and/or liquid vehicle). The composition may be a photosensitive composition.

Since the details for the quantum dot in the composition are the same as those of the quantum dot according to the embodiment described above, detailed descriptions thereof will be omitted.

The content of the quantum dot in the composition may be appropriately adjusted in consideration of the end use (e.g., such as a color conversion layer of an emission type color filter or a color conversion panel). In the composition (or composite), the content of quantum dot(s) may be greater than or equal to about 1 wt %, for example, greater than or equal to about 2 wt %, greater than or equal to about 3 wt %, greater than or equal to about 4 wt %, greater than or equal to about 5 wt %, greater than or equal to about 6 wt %, greater than or equal to about 7 wt %, greater than or equal to about 8 wt %, greater than or equal to about 9 wt %, greater than or equal to about 10 wt %, greater than or equal to about 15 wt %, greater than or equal to about 20 wt %, greater than or equal to about 25 wt %, greater than or equal to about 30 wt %, greater than or equal to about 35 wt %, or greater than or equal to about 40 wt % based on a total weight or total solids of the composition or composite. The content of the quantum dot may be less than or equal to about 70 wt %, less than or equal to about 65 wt %, less than or equal to about 60 wt %, less than or equal to about 55 wt %, less than or equal to about 50 wt %, less than or equal to about 45 wt %, less than or equal to about 40 wt %, or less than or equal to about 30 wt % based on a total weight or total solids of the composition or composite.

Here, for example, when the composition includes an organic solvent, the content based on the total solid content in the composition may correspond to the content of the corresponding component in the quantum dot composite. For example, when the quantum dot composition is a solvent-free system not including an organic solvent, the content range in the composition may correspond to the content range in the composite.

Meanwhile, a total amount of the compound represented by Chemical Formula 1 and the compound represented by Chemical Formula 2 present on the surface of the quantum dot in the composition may be greater than or equal to about 1 wt %, greater than or equal to about 2 wt %, greater than or equal to about 3 wt %, for example, greater than or equal to about 5 wt %, greater than or equal to about 7 wt %, greater than or equal to about 9 wt %, greater than or equal to about 10 wt %, greater than or equal to about 13 wt %, greater than or equal to about 15 wt %, greater than or equal to about 18 wt %, greater than or equal to about 20 wt %, greater than or equal to about 22 wt %, greater than or equal to about 25 wt %, greater than or equal to about 28 wt %, greater than or equal to about 30 wt %, greater than or equal to about 33 wt %, greater than or equal to about 35 wt %, greater than or equal to about 37 wt %, greater than or equal to about 40 wt %, greater than or equal to about 43 wt %, greater than or equal to about 45 wt %, or greater than or equal to about 47 wt % based on a total weight of solids in the composition or a total weight of the quantum dot composite produced from the composition. In addition, the total amount of the compound represented by Chemical Formula 1 and the compound represented by Chemical Formula 2 present on the surface of the quantum dot in the composition may be less than or equal to about 50 wt %, less than or equal to about 45 wt %, less than or equal to about 40 wt %, less than or equal to about 35 wt %, less than or equal to about 30 wt %, less than or equal to about 25 wt %, less than or equal to about 20 wt %, less than or equal to about 18 wt %, less than or equal to about 15 wt %, less than or equal to about 13 wt %, less than or equal to about 10 wt %, less than or equal to about 8 wt %, or less than or equal to about 5 wt % based on a total weight of solids in the composition or a total weight of the quantum dot composite produced from the composition.

The dispersant may contribute to ensuring dispersibility of quantum dot or metal oxide particulates, which will be described later. In an embodiment, the dispersant may be, for example, an organic compound having a carboxyl group, such as a monomer or a polymer, and may include, for example, a binder polymer. The dispersant or binder polymer may be an insulating polymer.

The organic compound having the carboxyl group may include a combination of monomers including a first monomer having a carboxyl group and a carbon-carbon double bond, a second monomer having a carbon-carbon double bond and a hydrophobic moiety and not having a carboxyl group, and optionally a third monomer having a carbon-carbon double bond and a hydrophilic moiety and not having a carboxyl group, or a copolymer thereof; a multi-aromatic ring-containing polymer (hereinafter, cardo binder) having a backbone in which two aromatic rings in a main chain are bound to quaternary carbon atoms that are constituent atoms of other cyclic moieties, and having a carboxyl group; or a combination thereof.

The dispersant may include the first monomer, the second monomer, and optionally the third monomer.

As described above, the quantum dot according to an embodiment includes both the compound represented by Chemical Formula 1 and the compound represented by Chemical Formula 2 on the surface, and since the compound represented by Chemical Formula 1 includes a hydrophilic group at one terminal end other than the terminal end that bound to the quantum dot, the quantum dot according to an embodiment is well mixed with the dispersant or binder polymer forming the composition, so that the quantum dots are uniformly dispersed in the composition. In addition, the compound represented by Chemical Formula 2 includes a carbon-carbon double bond at the opposite terminal end other than the terminal end that bound to the quantum dot, so that when the composition is cured, the carbon-carbon double bond present at the terminal end of the compound represented by Chemical Formula 2 may form a bond with the carbon-carbon double bond present in the dispersant or binder polymer in the composition through radical polymerization. Thereby, in the quantum dot composite produced from the composition including quantum dots according to an embodiment, the polymer matrix produced from the dispersant or binder polymer and the compound represented by Chemical Formula 2 bound to the surface of the quantum dot are firmly bound through chemical bonding, thereby forming the quantum dot that can be bound more stably with this polymer matrix. Therefore, the quantum dot composite produced from the composition according to an embodiment is thought to exhibit high reliability, with an initial luminance maintenance rate of greater than or equal to about 90%, for example, greater than or equal to about 95%, for example, greater than or equal to about 97%, even when driven for a long time under high luminance conditions.

A content of the dispersant (or binder polymer) in the composition may be greater than or equal to about 0.5 wt %, for example, greater than or equal to about 1 wt %, greater than or equal to about 5 wt %, greater than or equal to about 10 wt %, greater than or equal to about 15 wt %, greater than or equal to about 20 wt %, greater than or equal to about 30 wt %, greater than or equal to about 40 wt %, or greater than or equal to about 50 wt % based on a total solid content of the composition or a total weight of the quantum dot composite produced from the composition, but is not limited thereto. The content of the dispersant (or binder polymer) may be less than or equal to about 60 wt %, less than or equal to about 50 wt %, less than or equal to about 40 wt %, less than or equal to about 35 wt %, less than or equal to about 33 wt %, less than or equal to about 30 wt %, less than or equal to about 20 wt %, or less than or equal to about 10 wt % based on a total solid content of the composition or a total weight of the quantum dot composite produced therefrom. The content of the dispersant (or binder polymer) may be about 0.5 wt % to about 55 wt % based on a total solid content of the composition or a total weight of the quantum dot composite produced therefrom.

The polymerizable (e.g., photopolymerizable) monomer including the carbon-carbon double bond may include a (e.g., photopolymerizable) (meth)acrylic monomer. The monomer may be a precursor for the insulating polymer.

The content of the monomer may be greater than or equal to about 0.5 wt %, for example, greater than or equal to about 1 wt %, greater than or equal to about 2 wt %, greater than or equal to about 5 wt %, greater than or equal to about 10 wt %, greater than or equal to about 15 wt %, greater than or equal to about 20 wt %, greater than or equal to about 25 wt %, or greater than or equal to about 30 wt % based on a total solid content of the composition or a total weight of the quantum dot composite produced therefrom. The content of the monomer may be less than or equal to about 60 wt %, less than or equal to about 50 wt %, less than or equal to about 40 wt %, less than or equal to about 30 wt %, less than or equal to about 28 wt %, less than or equal to about 25 wt %, less than or equal to about 23 wt %, less than or equal to about 20 wt %, less than or equal to about 18 wt %, less than or equal to about 17 wt %, less than or equal to about 16 wt %, or less than or equal to about 15 wt % based on a total solid content of the composition or a total weight of the quantum dot composite produced therefrom.

The (photo)initiator included in the composition may be used for (photo)polymerization of the aforementioned monomer. The initiator is a compound accelerating a radical reaction (e.g., radical polymerization of monomer) by producing radical chemical species under a mild condition (e.g., by heat or light). The initiator may be a thermal initiator or a photoinitiator. The initiator is not particularly limited and may be appropriately selected.

A content of the initiator may be appropriately adjusted considering types and contents of the polymerizable monomers. In an embodiment, the content of the initiator may be greater than or equal to about 0.01 wt %, for example, greater than or equal to about 1 wt %, greater than or equal to about 5 wt %, greater than or equal to about and/or 10 wt %, less than or equal to about for example, 9 wt %, less than or equal to about 8 wt %, less than or equal to about 7 wt %, less than or equal to about 6 wt %, or less than or equal to about 5 wt % based on a total weight of the composition, but is not limited thereto.

The composition may further include a (multi- or monofunctional) thiol compound having at least one thiol group at the terminal end, metal oxide particulates, or a combination thereof.

The metal oxide particulates may include TiO₂, SiO₂, BaTiO₃, Ba₂TiO₄, ZnO, or a combination thereof. In an embodiment, the metal oxide particulates may be TiO₂.

The content of the metal oxide particulates in the composition may be greater than or equal to about 1 wt %, greater than or equal to about 5 wt %, greater than or equal to about 10 wt %, greater than or equal to about 15 wt %, greater than or equal to about 20 wt %, greater than or equal to about 25 wt %, greater than or equal to about 30 wt %, or greater than or equal to about 35 wt % and/or less than or equal to about 60 wt %, less than or equal to about 50 wt %, less than or equal to about 40 wt %, less than or equal to about 30 wt %, less than or equal to about 25 wt %, less than or equal to about 20 wt %, less than or equal to about 15 wt %, less than or equal to about 10 wt %, or less than or equal to about 5 wt % based on a total solid content of the composition or a total weight of the quantum dot composite produced therefrom. The metal oxide particulates may be non-luminescent. Herein, the term metal oxide may include oxides of a metal or a semi-metal.

A diameter of a metal oxide fine particle is not particularly limited and may be appropriately selected. A diameter of the metal oxide particulates may be greater than or equal to about 100 nm, for example, greater than or equal to about 150 nm, or greater than or equal to about 200 nm, and less than or equal to about 1000 nm, less than or equal to about 800 nm, less than or equal to about 500 nm, less than or equal to about 400 nm, or less than or equal to about 300 nm.

The thiol compound included in the composition may be represented by Chemical Formula 3:

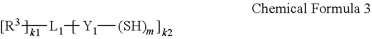

In Chemical Formula 3,
R³ is hydrogen; a substituted or unsubstituted C1 to C30 linear or branched alkyl group; a substituted or unsubstituted C6 to C30 aryl group; a substituted or unsubstituted C3 to C30 heteroaryl group; a substituted or unsubstituted C3 to C30 cycloalkyl group; a substituted or unsubstituted C3 to C30 heterocycloalkyl group; a C1 to C10 alkoxy group; a hydroxy group; —NH₂; a substituted or unsubstituted C1 to C30 amine group (—NRR′, wherein R and R′ are each independently hydrogen or a C1 to C30 linear or branched alkyl group and not hydrogen at the same time); an isocyanate group; a halogen; —ROR′ wherein R is a substituted or unsubstituted C1 to C20 alkylene group and R′ is hydrogen or a C1 to C20 linear or branched alkyl group; an acyl halide (—RC(═O)X, wherein R is a substituted or unsubstituted alkylene group and X is a halogen); —C(═O)OR′ (wherein R′ is hydrogen or a C1 to C20 linear or branched alkyl group); —CN; —C(═O)ORR′ or —C(═O)ONRR′ (wherein R and R′ are each independently hydrogen or a C1 to C20 linear or branched alkyl group), L₁ is a carbon atom, a substituted or unsubstituted C1 to C30 alkylene group, a substituted or unsubstituted C1 to C30 alkylene group in which at least one methylene (—CH₂—) is replaced by sulfonyl (—SO₂—), carbonyl (CO), ether (—O—), sulfide (—S—), sulfoxide (—SO—), ester (—C(═O)O—), amide (—C(═O)NR—, wherein R is hydrogen or a C1 to C10 alkyl group), or a combination thereof, a substituted or unsubstituted C3 to C30 cycloalkylene group, a substituted or unsubstituted C6 to C30 arylene group, a substituted or unsubstituted C3 to C30 heteroarylene group, or a substituted or unsubstituted C3 to C30 heterocycloalkylene moiety,
Y₁ is a single bond; a substituted or unsubstituted C1 to C30 alkylene group; a substituted or unsubstituted C2 to C30 alkenylene group; or a C1 to C30 alkylene group or a C2 to C30 alkenylene group in which at least one methylene (—CH₂—) is replaced by sulfonyl (—S(═O)₂—), carbonyl (—C(═O)—), ether (—O—), sulfide (—S—), sulfoxide (—S(═O)—), ester (—C(═O)O—), amide (—C(═O)NR—, wherein R is hydrogen or a C1 to C10 linear or branched alkyl group), imine (—NR—, wherein R is hydrogen or a C1 to C10 linear or branched alkyl group), or a combination thereof,
m is an integer of greater than or equal to 1,
k1 is 0 or an integer of greater than or equal to 1 and k2 is an integer of greater than or equal to 1,
a sum of m and k2 is an integer of greater than or equal to 3,
m does not exceed the valence of Y₁, and
a sum of k1 and k2 does not exceed the valence of L₁.

The (multi) thiol compound may be a dithiol compound, a trithiol compound, a tetrathiol compound, or a combination thereof. For example, the thiol compound may be glycoldi-3-mercaptopropionate, glycoldimercapto acetate, trimethylolpropanetris (3-mercaptopropionate), pentaerythritol tetrakis (3-mercaptopropionate), pentaerythritol tetrakis (2-mercaptoacetate), 1,6-hexanedithiol, 1,3-propanedithiol, 1,2-ethanedithiol, polyethylene glycol dithiol including 1 to 10 ethylene glycol repeating units, or a combination thereof.

A content of the (multi) thiol compound may be less than or equal to about 60 wt %, less than or equal to about 50 wt %, less than or equal to about 40 wt %, less than or equal to about 30 wt %, less than or equal to about 20 wt %, less than or equal to about 10 wt %, less than or equal to about 9 wt %, less than or equal to about 8 wt %, less than or equal to about 7 wt %, less than or equal to about 6 wt %, or less than or equal to about 5 wt % based on a total solid content of the composition or a total weight of the quantum dot composite produced therefrom. The content of the (multi) thiol compound may be greater than or equal to about 0.1 wt %, for example, greater than or equal to about 0.5 wt %, greater than or equal to about 1 wt %, greater than or equal to about 5 wt %, greater than or equal to about 10 wt %, greater than or equal to about 15 wt %, greater than or equal to about 20 wt %, or greater than or equal to about 25 wt % based on a total solid content of the composition or a total weight of the quantum dot composite produced therefrom.

The composition may further include an organic solvent (or liquid vehicle, hereinafter referred to as a solvent). The type of useable solvent is not particularly limited. Non-limiting examples of the solvent or liquid vehicle may be ethyl 3-ethoxy propionate; ethylene glycols such as ethylene glycol, diethylene glycol, polyethylene glycol, and the like; glycolethers such as ethylene glycolmonomethylether, ethylene glycolmonoethylether, diethylene glycolmonomethylether, ethylene glycoldiethylether, diethylene glycoldimethylether, and the like; glycoletheracetates such as ethylene glycolacetate, ethylene glycolmonoethyletheracetate, diethylene glycolmonoethyletheracetate, diethylene glycolmonobutyletheracetate, and the like; propylene glycols such as propylene glycol, and the like; propylene glycolethers such as propylene glycolmonomethylether, propylene glycolmonoethylether, propylene glycolmonopropylether, propylene glycolmonobutylether, propylene glycoldimethylether, dipropylene glycoldimethylether, propylene glycoldiethylether, dipropylene glycoldiethylether, and the like; propylene glycoletheracetates such as propylene glycolmonomethyl ether acetate, dipropylene glycolmonoethyletheracetate, and the like; amides such as N-methylpyrrolidone, dimethyl formamide, dimethyl acetamide, and the like; ketones such as dimethylsulfoxide; methylethylketone (MEK), methylisobutylketone (MIBK), cyclohexanone, and the like; petroleums such as solvent naphtha, and the like; esters such as ethyl acetate, butyl acetate, ethyl lactate, and the like; ethers such as tetrahydrofuran, diethyl ether, dipropyl ether, dibutyl ether, and the like, chloroform, C1 to C40 aliphatic hydrocarbon (e.g., alkane, alkene, or alkyne), a halogen—(e.g., chlorine-)substituted C1 to C40 aliphatic hydrocarbon (e.g., dichloroethane, trichloromethane, and the like), C6 to C40 aromatic hydrocarbon (e.g., toluene, xylene, and the like), a halogen—(e.g., chlorine-) substituted C6 to C40 aromatic hydrocarbon or a combination thereof, but are not limited thereto.

The types and contents of the organic solvent may be appropriately determined by considering the aforementioned main components (i.e., the quantum dot, the dispersant, the polymerizable monomer, the initiator, and if used, the thiol compound,) and types and contents of additives which is described later. The composition may include a solvent in a residual amount except for a desired content of the (non-volatile) solid.

The composition (e.g., inkjet composition) may have a viscosity at 25° C. of greater than or equal to about 4 centipoise (cPs), greater than or equal to about 5 cPs, greater than or equal to about 5.5 cPs, greater than or equal to about 6.0 cPs, or greater than or equal to about 7.0 cPs. The composition may have a viscosity at 25° C. of less than or equal to about 12 cPs, less than or equal to about 10 cPs, or less than or equal to about 9 cPs.

When used for inkjet, the composition may be discharged to a substrate at room temperature, and may be heated, for example, to form a quantum dot-polymer composite film or a pattern thereof. The ink composition, while having the aforementioned viscosity, may have a surface tension at 23° C. of greater than or equal to about 21 milliNewtons per meter (mN/m), greater than or equal to about 22 mN/m, greater than or equal to about 23 mN/m, greater than or equal to about 24 mN/m, greater than or equal to about 25 mN/m, greater than or equal to about 26 mN/m, greater than or equal to about 27 mN/m, greater than or equal to about 28 mN/m, greater than or equal to about 29 mN/m, greater than or equal to about 30 mN/m, or greater than or equal to about 31 mN/m and less than or equal to about 40 mN/m, less than or equal to about 39 mN/m, less than or equal to about 38 mN/m, less than or equal to about 36 mN/m, less than or equal to about 35 mN/m, less than or equal to about 34 mN/m, less than or equal to about 33 mN/m, or less than or equal to about 32 mN/m. The ink composition may have a surface tension of less than or equal to about 31 mN/m, less than or equal to about 30 mN/m, less than or equal to about 29 mN/m, or less than or equal to about 28 mN/m.

In an embodiment, the composition may further include, for example, an additive included in the composition for photoresist or the ink composition. The additive may include a light diffusing agent, a leveling agent, a coupling agent, and the like. For specific details, for example, reference may be made to the contents described in US-2017-0052444-A1.

The composition may be prepared by a method that includes preparing a quantum dot dispersion including the aforementioned quantum dot, dispersant, and/or solvent, and mixing an initiator, a polymerizable monomer (e.g., an acrylic monomer), optionally a thiol compound, metal oxide particulates, and optionally the aforementioned additives in the quantum dot dispersion. Each of the aforementioned components may be mixed sequentially or simultaneously, and the order is not particularly limited.

The composition may be used to provide a quantum dot composite according to an embodiment, for example, a quantum dot-polymer composite. The composition may provide, for example, a quantum dot-polymer composite by radical polymerization. The composition for producing a quantum dot composite according to an embodiment may be a quantum dot-containing photoresist composition applicable to a photolithography method. The composition according to an embodiment may be an ink composition capable of providing a pattern by a printing method (e.g., a droplet discharging method such as inkjet printing).

Therefore, the quantum dot composite according to an embodiment includes a polymer matrix and the aforementioned quantum dot dispersed in the matrix, and is configured to emit green light, wherein the plurality of quantum dots include a semiconductor nanocrystal core including indium and phosphorus.

In an embodiment, the plurality of quantum dots included in the quantum dot composite may further include a semiconductor nanocrystal shell including zinc, selenium, and sulfur, which is disposed on the semiconductor nanocrystal core including indium and phosphorus. The quantum dot composite according to an embodiment including such quantum dots may include about 0.5 wt % to about 2.5 wt % of indium, about 10 wt % to about 25 wt % of zinc, about 4.5 wt % to about 15 wt % of selenium, and about 5 wt % to about 15 wt % of sulfur based on the total weight of the quantum dot composite.

The contents of the elements in the quantum dot composite can be confirmed through inductively coupled plasma (ICP) emission spectroscopy or the like.

Based on the total weight of the quantum dot composite, the content of the plurality of quantum dots may be greater than or equal to about 10%, greater than or equal to about 20%, greater than or equal to about 30%, greater than or equal to about 40%, greater than or equal to about 50%, or greater than or equal to about 60%, for example, greater than or equal to about 10% and less than or equal to about 60%, greater than or equal to about 15% and less than or equal to about 60%, greater than or equal to about 20% and less than or equal to about 60%, greater than or equal to about 25% and less than or equal to about 60%, greater than or equal to about 30% and less than or equal to about 60%, greater than or equal to about 30% and less than or equal to about 55%, greater than or equal to about 35% and less than or equal to about 55%, greater than or equal to about 40% and less than or equal to about 55%, greater than or equal to about 45% and less than or equal to about 60%, greater than or equal to about 45% and less than or equal to about 55%, or about 50%, but is not limited thereto.

Based on the total weight of the quantum dot composite, the content of the matrix may be greater than or equal to about 10%, greater than or equal to about 20%, greater than or equal to about 30%, greater than or equal to about 40%, greater than or equal to about 50%, greater than or equal to about 60%, or greater than or equal to about 70% and less than or equal to about 90%, less than or equal to about 80%, less than or equal to about 70%, less than or equal to about 60%, less than or equal to about 50%, or less than or equal to about 40%, for example, greater than or equal to about 10% and less than or equal to about 90%, greater than or equal to about 20% and less than or equal to about 85%, greater than or equal to about 25% and less than or equal to about 80%, greater than or equal to about 30% and less than or equal to about 75%, greater than or equal to about 30% and less than or equal to about 70%, greater than or equal to about 30% and less than or equal to about 65%, greater than or equal to about 30% and less than or equal to about 60%, greater than or equal to about 30% and less than or equal to about 55%, greater than or equal to about 35% and less than or equal to about 55%, greater than or equal to about 35% and less than or equal to about 50%, greater than or equal to about 30% and less than or equal to about 45%, or greater than or equal to about 30% and less than or equal to about 40%, or greater than or equal to about 35% and less than or equal to about 45%, but is not limited thereto.

The (polymer) matrix may include a crosslinked polymer and/or a linear polymer. The crosslinked polymer may include a thiolene resin, a crosslinked poly(meth)acrylate, a crosslinked polyurethane, a crosslinked epoxy resin, a crosslinked vinyl polymer, a crosslinked silicone resin, or a combination thereof. The linear polymer may include a carboxylic acid-containing repeating unit.

The matrix may include the aforementioned dispersant (e.g., a carboxyl group-containing monomer or polymer), a polymerization product of a polymerizable monomer including at least one carbon-carbon double bond, for example 2 or more, 3 or more, 4 or more, or 5 or more, such as an insulating polymer, and optionally a polymerization product between the polymerizable monomer and thiol compounds having at least one, for example, two or more thiol groups at the terminal end. In addition, the polymer matrix may include a polymerization product between the compound represented by Chemical Formula 2 bound to the surface of the quantum dot according to an embodiment and the polymerizable monomer or a thiol compound having at least one, for example, two or more thiol groups at the terminal end.

In an embodiment, the polymer matrix may include a crosslinked polymer, a linear polymer, or a combination thereof. The crosslinked polymer may include a thiolene resin, a crosslinked poly(meth)acrylate, or a combination thereof. In an embodiment, the crosslinked polymer may be a polymerization product of the aforementioned polymerizable monomer, and optionally a (multi) thiol compound. Details for the quantum dot, dispersant, polymerizable monomer, and (multi) thiol compound are the same as described above.

The quantum dot composite may be in the form of a film, for example, in the form of a patterned film. The patterning may be performed using a photolithographic method or the like by including photocurable materials as the dispersant or the photopolymerizable monomer in the composition for preparing the quantum dot composite. Alternatively, it may be printed in a patterned form through an inkjet printing process or the like. This is described in more detail below.

A display panel according to another embodiment may include the quantum dot composite. The display panel may include a color conversion layer including a plurality of regions including a color conversion region, and the aforementioned quantum dot composite according to the embodiment may be disposed in the color conversion region in the color conversion layer. In an embodiment, the color conversion layer may further include a partition wall defining the plurality of regions.

In an embodiment, the display panel may further include a light emitting panel including a light emitting source, and the color conversion layer may convert an emission spectrum of light emitted from the light emitting panel. For example, the color conversion layer may absorb blue light emitted from the light emitting source and convert it into green light or red light.

In an embodiment, the color conversion layer may be in a form of a patterned film.

In an embodiment, the color conversion region of the color conversion layer may include at least one first region (hereinafter also referred to as a first partition) configured to convert the light irradiated by the excitation light into light of a first emission spectrum and emit it, and the first region may include the quantum dot composite according to an embodiment. The color conversion layer may be in a form of a quantum dot composite patterned film.

The color conversion region may include a (e.g., one or more) second region (hereinafter also referred to as a second partition) configured to emit a second light different from the first light (e.g., by irradiation of excitation light). The second region may include a quantum dot composite according to an embodiment.

The quantum dot composite in the second region may include quantum dots that emit light of a different wavelength (e.g., a different color) from the quantum dot composite in the first region.

The first light or the second light may be red light having an emission peak wavelength of about 610 nm to about 660 nm (e.g., about 620 nm to about 650 nm), or green light having an emission peak wavelength of about 500 nm to about 550 nm (e.g., about 510 nm to about 540 nm). The color conversion layer may further include (at least one) a third region (hereinafter also referred to as a third partition) that emits or passes a third light (e.g., blue light) different from the first light and the second light. The third light may include excitation light. The third light may include blue light having an emission peak wavelength in a range of about 430 nm to about 470 nm.

In an embodiment, in the first region configured to emit the first light, that is, red light having an emission peak wavelength of about 610 nm to about 660 nm (e.g., about 620 nm to about 650 nm) in the color conversion region, the content of indium may be about 1 wt % to about 1.5 wt %, the content of zinc may be about 10 wt % to about 20 wt %, the content of selenium may be about 5 wt % to about 10 wt %, and the content of sulfur may be about 5 wt % to about 10 wt % based on a total weight of the materials forming the first region.

In an embodiment, in the second region configured to emit the second light, that is, green light having an emission peak wavelength of about 500 nm to about 550 nm (e.g., about 510 nm to about 540 nm), in the color conversion region, the content of indium may be about 0.5 wt % to about 2 wt %, the content of zinc may be about 15 wt % to about 25 wt %, the content of selenium may be about 4.5 wt % to about 15 wt %, and the content of sulfur may be about 6 wt % to about 15 wt % based on a total weight of the materials forming the second region.

The content of the elements in the color conversion region in the color conversion layer of the display panel may be confirmed through ICP emission spectroscopy or the like.

The color conversion layer (or the patterned film of the quantum dot composite) may be produced using a photoresist composition. This method may include forming a film of the composition for producing a quantum dot composite according to an embodiment on a substrate (S1); prebaking the film according to selection (S2); exposing a selected region of the film to light (e.g., having a wavelength of less than or equal to about 400 nm) (S3); and developing the exposed film with an alkali developing solution to obtain a pattern of a quantum dot polymer composite (S4).

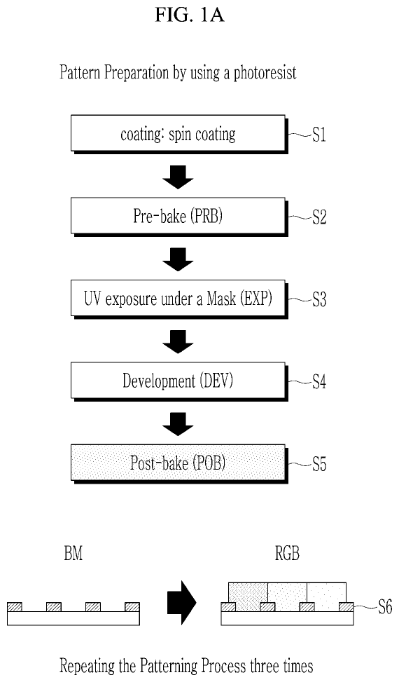

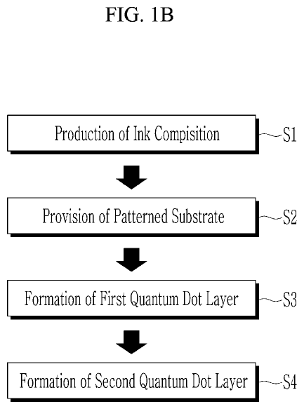

Referring to FIG. 1A, the aforementioned composition is applied to a predetermined thickness on a substrate using an appropriate method such as spin coating or slit coating to form a film. The formed film may be optionally subjected to a pre-baking (PRB). The pre-baking may be performed by selecting an appropriate condition from known conditions of a temperature, time, an atmosphere, and the like.

The formed (or optionally prebaked) film is exposed to light having a predetermined wavelength under a mask having a predetermined pattern. A wavelength and intensity of the light may be selected considering types and contents of the photoinitiator, types and contents of the quantum dot, and the like.

The exposed film is treated with an alkali developing solution (e.g., dipping or spraying) to dissolve an unexposed region and obtain a desired pattern. The obtained pattern may be, optionally, post-baked (POB) to improve crack resistance and solvent resistance of the pattern, for example, at a temperature of about 150° C. to about 230° C. for a predetermined time (e.g., greater than or equal to about 10 minutes or greater than or equal to about 20 minutes).

When the color conversion layer or the patterned film of the quantum dot composite has a plurality of repeating partitions (that is, color conversion regions), each repeating partition may be formed by preparing a plurality of compositions including quantum dots (e.g., red light emitting quantum dots, green quantum dots, or optionally, blue quantum dots) having desired luminous properties (emission peak wavelength and the like) and repeating the aforementioned pattern-forming process as many times as necessary (e.g., 2 times or more, or 3 times or more) for each composition, resultantly obtaining a quantum dot-polymer composite having a desired pattern. For example, the quantum dot-polymer composite may have a pattern of at least two repeating color partitions (e.g., RGB color partitions). This quantum dot-polymer composite pattern may be used as a photoluminescence-type color filter in a display device.

The color conversion layer or the patterned film of the quantum dot composite may be produced using an ink composition configured to form a pattern in an inkjet manner. Referring to FIG. 1B, such a method may include preparing an ink composition according to an embodiment, providing a substrate (e.g., with pixel areas patterned by electrodes and optionally banks, etc.), depositing an ink composition on the substrate (or the pixel region) to form, for example, a first quantum dot layer (or first region); and depositing an ink composition on the substrate (or the pixel region) to form, for example, a second quantum dot layer (or second region). The forming of the first quantum dot layer and the forming of the second quantum dot layer are simultaneously or sequentially carried out.

The depositing of the ink composition may be performed using an appropriate liquid crystal discharger, for example an inkjet or nozzle printing system having an ink storage and at least one print head. The deposited ink composition may provide a first or second quantum dot layer through the solvent removal and polymerization by the heating. The method may provide a highly precise quantum dot-polymer composite film or patterned film for a short time by the simple method.

The aforementioned quantum dot or quantum dot composite (pattern) may be included in an electronic device. Such an electronic device may include, but are not limited to, a display device, a light emitting diode (LED), an organic light emitting diode (OLED), a quantum dot LED, a sensor, a solar cell, an imaging sensor, a photodetector, or a liquid crystal display device. The aforementioned quantum dot may be included in an electronic apparatus. Such an electronic apparatus may include a portable terminal device, a monitor, a notebook computer, a television, an electric sign board, a camera, a VR (virtual reality) or AR (augmented reality) device, a car, and the like, but is not limited thereto. The electronic apparatus may be a portable terminal device including a display device (or a light emitting device) including the quantum dot, a monitor, a notebook computer, an electronic display board, a television, a VR (virtual reality), AR (augmented reality) device, and the like. The electronic apparatus may be a camera or a mobile terminal device including an image sensor including the quantum dot. The electronic apparatus may be a camera or a vehicle including a photodetector including the quantum dot.

Hereinafter, the display panel and the color conversion panel will be described in more detail with reference to the drawings.

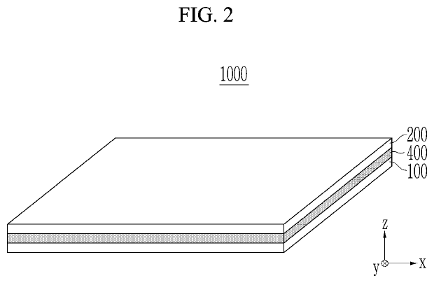

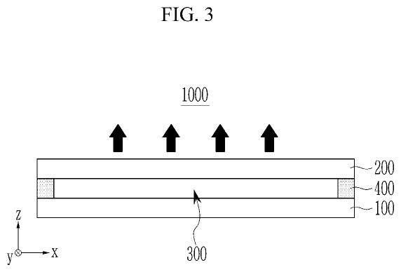

Referring to FIGS. 2 and 3, a display panel 1000 according to an embodiment includes a light emitting panel 100, a color conversion panel 200, a light transmitting layer 300 disposed between the light emitting panel 100 and the color conversion panel 200, and a binder 400 bonding the light emitting panel 100 and the color conversion panel 200.

The light emitting panel 100 and the color conversion panel 200 may face each other with the light transmitting layer 300 between, and the color conversion panel 200 may be disposed in a direction in which light is emitted from the light emitting panel 100. The binder 400 may be disposed along the edges of the light emitting panel 100 and the color conversion panel 200, and may be, for example, a sealant.

In FIGS. 2 and 3, the light transmitting layer 300 is disposed between the light emitting panel 100 and the color conversion panel 200, and the binder 400 is disposed along the edges of the light emitting panel 100 and the color conversion panel 200. However, the light transmitting layer 300 and the binder 400 may be omitted and are not necessarily included. That is, the light emitting panel 100 and the color conversion panel 200 may be directly coupled without interposing the light transmitting layer 300.

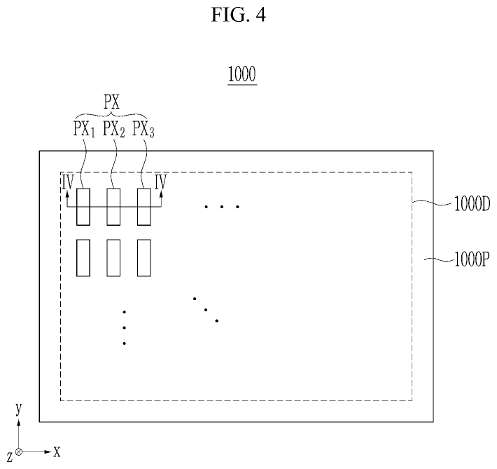

Referring to FIG. 4, a display panel 1000 according to an embodiment includes a display area 1000D for displaying an image and a non-display area 1000P disposed around the display area 1000D and in which the binding element 400 is disposed.

The display area 1000D may include a plurality of pixels PXs arranged along a row (e.g., x direction) and/or a column (e.g., y direction), and each pixel PX may include a plurality of subpixels PX₁, PX₂, and PX₃ displaying different colors. Herein, as an example, a configuration in which three subpixels PX₁, PX₂, and PX₃ constitute one pixel PX is illustrated, but the configuration is not limited thereto. An additional subpixel such as a white subpixel may be further included, and one or more subpixel displaying the same color may be included. The plurality of pixels PXs may be arranged in, for example, a Bayer matrix, a PenTile matrix, and/or a diamond matrix, but is not limited thereto.

Each of the subpixels PX₁, PX₂, and PX₃ may be configured to display a color of three primary colors or a combination of three primary colors, for example, red, green, blue, or a combination thereof. For example, the first subpixel PX₁ may be configured to display red, the second subpixel PX₂ may be configured to display green, and the third subpixel PX₃ may be configured to display blue.

In the drawing, an example in which all subpixels have the same size is illustrated, but the present disclosure is not limited thereto. At least one of the subpixels may be larger or smaller than the other subpixels. In the drawing, an example in which all subpixels have the same shape is illustrated, but the present disclosure is not limited thereto. At least one of the subpixels may have a different shape from other subpixels.

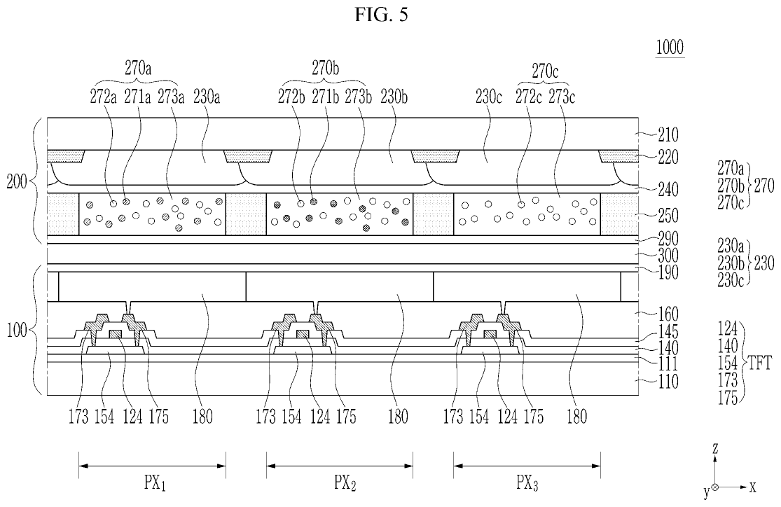

The light emitting panel 100 and the color conversion panel 200 will be described with reference to FIG. 5.

The light emitting panel 100 may include a light emitting device that emits light in a predetermined wavelength region and a circuit device for switching and/or driving the light emitting device. Specifically, the light emitting panel 100 may include a lower substrate 110, a buffer layer 111, a thin film transistor (TFT), a light emitting device 180, and an encapsulation layer 190.

The lower substrate 110 may be a glass substrate or a polymer substrate. The polymer substrate may include, for example, polyimide, polyamide, polyamideimide, polyethylene terephthalate, polyethylene naphthalene, polymethyl methacrylate, polycarbonate, a copolymer thereof, or a combination thereof, but is not limited thereto.

The buffer layer 111 may include an organic material, an inorganic material, or an organic-inorganic material. The buffer layer 111 may include, for example, an oxide, a nitride, or an oxynitride, and may include, for example, silicon oxide, silicon nitride, silicon oxynitride, or a combination thereof, but is not limited thereto. The buffer layer 111 may be one layer or two or more layers, and may cover the whole surface of the lower substrate 110. The buffer layer 111 may be omitted.

The thin film transistor TFT may be a three terminal element for switching and/or driving the light emitting device 180, which will be described later, and one or two or more may be included for each subpixel. The thin film transistor TFT may include a gate electrode 124, a semiconductor layer 154 overlapped with the gate electrode 124, a gate insulating layer 140 between the gate electrode 124 and the semiconductor layer 154, and a source electrode 173 and a drain electrode 175 electrically connected to the semiconductor layer 154. In the drawings, a coplanar top gate structure is shown as an example, but the structure is not limited thereto and may have various structures.

The gate electrode 124 is electrically connected to a gate line (not shown), and may include, for example, a low-resistance metal such as aluminum (Al), molybdenum (Mo), copper (Cu), titanium (Ti), silver (Ag), gold (Au), an alloy thereof, or a combination thereof, but is not limited thereto.

The semiconductor layer 154 may be an inorganic semiconductor such as amorphous silicon, polycrystalline silicon, or oxide semiconductor; an organic semiconductor; an organic-inorganic semiconductor; or a combination thereof. For example, the semiconductor layer 154 may include an oxide semiconductor including at least one of indium (In), zinc (Zn), tin (Sn), and gallium (Ga), and the oxide semiconductor may include, for example, indium-gallium-zinc oxide, zinc-tin oxide, or a combination thereof, but they are not limited thereto. The semiconductor layer 154 may include a channel region and doped regions disposed on both sides of the channel region and electrically connected to the source electrode 173 and the drain electrode 175, respectively.

The gate insulating layer 140 may include an organic material, an inorganic material, or an organic-inorganic material, and may include, for example, an oxide, a nitride, or an oxynitride, and may include, for example, silicon oxide, silicon nitride, silicon oxynitride, or a combination thereof, but is not limited thereto. In the drawing, an example in which the gate insulating layer 140 is formed on the whole surface of the lower substrate 110 is illustrated, but the present disclosure is not limited thereto and may be optionally formed between the gate electrode 124 and the semiconductor 154. The gate insulating layer 140 may be formed of one or two or more layers.

The source electrode 173 and the drain electrode 175 may include, for example, a low-resistance metal such as aluminum (Al), molybdenum (Mo), copper (Cu), titanium (Ti), silver (Ag), gold (Au), an alloy thereof, or a combination thereof, but are not limited thereto. The source electrode 173 and the drain electrode 175 may be electrically connected to the doped regions of the semiconductor layer 154, respectively. The source electrode 173 is electrically connected to a data line (not shown), and the drain electrode 175 is electrically connected to a light emitting device 180 to be described later.

An interlayer insulating layer 145 is additionally formed between the gate electrode 124 and the source/drain electrodes 173 and 175. The interlayer insulating layer 145 may include an organic material, an inorganic material, or an organic-inorganic material, for example, oxide, nitride, or oxynitride, for example, silicon oxide, silicon nitride, silicon oxynitride, or a combination thereof, but is not limited thereto. The interlayer insulating layer 145 may be formed of one or two or more layers.

A protective layer 160 is formed on the thin film transistor TFT. The protective layer 160 may be, for example, a passivation layer. The protective layer 160 may include an organic material, an inorganic material, or an organic-inorganic material, for example, polyacrylic, polyimide, polyamide, polyamideimide, or a combination thereof, but is not limited thereto. The protective layer 160 may be formed of one or two or more layers.

The light emitting device 180 may be disposed for each subpixel PX₁, PX₂, and PX₃, and the light emitting device 180 disposed in each subpixel PX₁, PX₂, and PX₃ may be independently driven. The light emitting device 180 may be, for example, a light emitting diode, and may include a pair of electrodes and a light emitting layer between the pair of electrodes. The light emitting layer may include a light emitting body capable of emitting light in a predetermined wavelength region, and for example, may include a light emitting body that emits light in a first emission spectrum belonging to a visible wavelength spectrum. The light emitting body may include an organic light emitting body, an inorganic light emitting body, an organic-inorganic light emitting body, or a combination thereof, and may be one type or two or more types.

The light emitting device 180 may be, for example, an organic light emitting diode, an inorganic light emitting diode, or a combination thereof. The inorganic light emitting diode may be, for example, a quantum dot light emitting diode, a perovskite light emitting diode, a micro light emitting diode, an inorganic nano light emitting diode, or a combination thereof, but is not limited thereto.

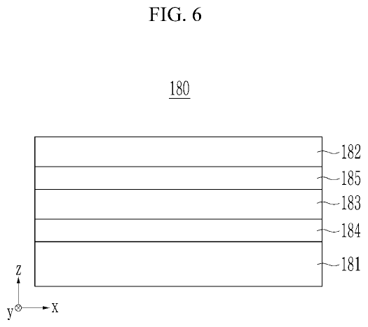

FIGS. 6 to 8 are cross-sectional views showing examples of light emitting devices, respectively.

Referring to FIG. 6, the light emitting device 180 includes a first electrode 181 and a second electrode 182 facing each other; a light emitting layer 183 between the first electrode 181 and the second electrode 182; and optionally auxiliary layers 184 and 185 between the first electrode 181 and the light emitting layer 183 and between the second electrode 182 and the light emitting layer 183.

The first electrode 181 and the second electrode 182 may be disposed to face each other along a thickness direction (for example, z direction), and any one of the first electrode 181 and the second electrode 182 may be an anode and the other may be a cathode. The first electrode 181 may be a light transmitting electrode, a transflective electrode, or a reflecting electrode, and the second electrode 182 may be a light transmitting electrode or a transflective electrode. The light transmitting electrode or transflective electrode may be, for example, made of a thin single layer or multiple layers of metal thin film including conductive oxides such as indium tin oxide (ITO), indium zinc oxide (IZO), zinc oxide (ZnO), tin oxide (SnO), aluminum tin oxide (AITO), and fluorine-doped tin oxide (FTO) or silver (Ag), copper (Cu), aluminum (Al), magnesium (Mg), magnesium-silver (Mg—Ag), magnesium-aluminum (Mg—Al), or a combination thereof. The reflecting electrode may include a metal, a metal nitride, or a combination thereof, for example, silver (Ag), copper (Cu), aluminum (Al), gold (Au), titanium (Ti), chromium (Cr), nickel (Ni), an alloy thereof, a nitride thereof (e.g., TiN), or a combination thereof, but is not limited thereto.

The light emitting layer 183 may include a light emitting body capable of emitting light of a specific wavelength. The specific wavelength may belong to a relatively short wavelength region of the visible light wavelength spectrum, and may be, for example, a blue light emission wavelength (and a green light emission wavelength if selected). The maximum emission wavelength of the blue emission may belong to a wavelength range of greater than or equal to about 400 nm and less than about 500 nm, and may belong to a wavelength range of about 410 nm to about 490 nm or about 420 nm to about 480 nm within the above range. The light emitting body may be one or two or more.

For example, the light emitting layer 183 may include a host material and a dopant material.

For example, the light emitting layer 183 may include a phosphorescent material, a fluorescent material, or a combination thereof.

For example, the light emitting body may include an organic light emitting body, and the organic light emitting body may be a low molecular weight compound, a polymer, or a combination thereof. When the light emitting body includes an organic light emitting body, the light emitting device 180 may be an organic light emitting diode.

For example, the light emitting body may include an inorganic light emitting body, and the inorganic light emitting body may be an inorganic semiconductor, quantum dot, perovskite, or a combination thereof. When the light emitting body includes an inorganic light emitting body, the light emitting device 180 may be a quantum dot light emitting diode, a perovskite light emitting diode, a micro light emitting diode, or a nano light emitting diode, but is not limited thereto.

The auxiliary layers 184 and 185 may be disposed between the first electrode 181 and the light emitting layer 183 and between the second electrode 182 and the light emitting layer 183, respectively, and may be a charge auxiliary layer to control injection and/or mobility of charges, respectively. Each of the auxiliary layers 184 and 185 may be one or two or more layers, and may be, for example, a hole injection layer, a hole transport layer, an electron blocking layer, an electron injection layer, an electron transport layer, a hole blocking layer, or a combination thereof. At least one of the auxiliary layers 184 and 185 may be omitted.

The light emitting devices 180 disposed in each of the subpixels PX₁, PX₂, and PX₃ may be the same or different from each other. The light emitting devices 180 disposed in each of the subpixels PX₁, PX₂, and PX₃ may emit light of the same emission spectrum, for example, each may emit light of a blue emission spectrum, for example, light of a blue emission spectrum having a maximum emission wavelength in a wavelength region of greater than or equal to about 400 nm and less than about 500 nm, about 410 nm to about 490 nm, or about 420 nm to about 480 nm. The light emitting devices 180 disposed in each of the subpixels PX₁, PX₂, and PX₃ may or may not be separated by a pixel defining layer (not shown).

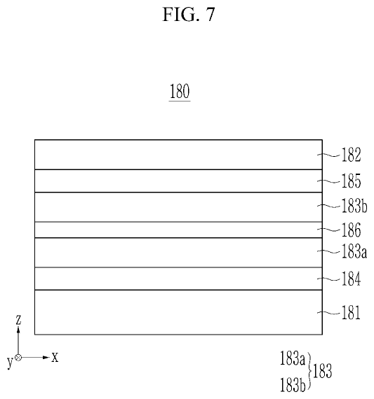

Referring to FIG. 7, the light emitting device 180 may be a light emitting device having a tandem structure, and includes a first electrode 181 and a second electrode 182 facing each other; a first light emitting layer 183a and a second light emitting layer 183b between the first electrode 181 and the second electrode 182; a charge generation layer 186 between the first light emitting layer 183a and the second light emitting layer 183b, and optionally auxiliary layers 184 and 185 between the first electrode 181 and the first light emitting layer 183a and between the second electrode 182 and the second light emitting layer 183b.

The first electrode 181, the second electrode 182, and the auxiliary layers 184 and 185 are as described above.

The first light emitting layer 183a and the second light emitting layer 183b may emit light having the same or different emission spectrum, and, for example, each may emit light having a blue emission spectrum. Detailed descriptions are the same as the light emitting layer 183 described above.

The charge generation layer 186 may inject electric charges into the first light emitting layer 183a and/or the second light emitting layer 183b, and may control a charge balance between the first light emitting layer 183a and the second light emitting layer 183b. The charge generation layer 186 may include, for example, an n-type layer and a p-type layer, and may include, for example, an electron transport material and/or a hole transport material including an n-type dopant and/or a p-type dopant. The charge generation layer 186 may be one layer or two or more layers.

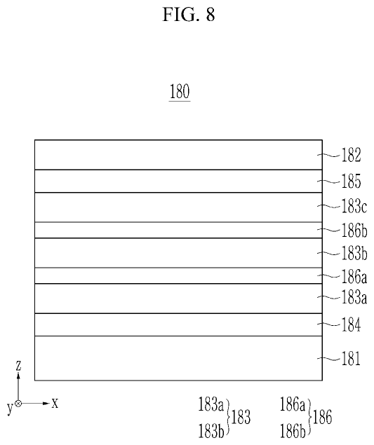

Referring to FIG. 8, the light emitting device 180 may be a light emitting device having a tandem structure, and includes a first electrode 181 and a second electrode 182 facing each other; a first light emitting layer 183a, a second light emitting layer 183b, and a third light emitting layer 183c between the first electrode 181 and the second electrode 182; a first charge generation layer 186a between the first light emitting layer 183a and the second light emitting layer 183b; a second charge generation layer 186b between the second light emitting layer 183b and the third light emitting layer 183c; and optionally, auxiliary layers 184 and 185 between the first electrode 181 and the first light emitting layer 183a and between the second electrode 182 and the third light emitting layer 183c.

The first electrode 181, the second electrode 182, and the auxiliary layers 184 and 185 are as described above.

The first light emitting layer 183a, the second light emitting layer 183b, and the third light emitting layer 183c may emit light having the same or different emission spectrum, and, for example, each may emit light having a blue emission spectrum. Detailed descriptions are the same as the light emitting layer 183 described above.

The first charge generation layer 186a may inject electric charges into the first light emitting layer 183a and/or the second light emitting layer 183b, and may control charge balances between the first light emitting layer 183a and the second light emitting layer 183b. The second charge generation layer 186a may inject electric charges into the second light emitting layer 183b and/or the third light emitting layer 183c, and may control charge balances between the second light emitting layer 183b and the third light emitting layer 183c. Each of the first and second charge generation layers 186a and 186b may be one layer or two or more layers.

Referring to FIGS. 2 to 5, the encapsulation layer 190 covers the light emitting device 180 and may include a glass plate, a metal thin film, an organic film, an inorganic film, an organic-inorganic film, or a combination thereof. The organic film may include, for example, an acrylic resin, a (meth)acrylic resin, polyisoprene, a vinyl resin, an epoxy resin, an urethane resin, a cellulose resin, a perylene resin, or a combination thereof, but is not limited thereto. The inorganic film may include, for example, an oxides, a nitride, and/or an oxynitride, for example silicon oxide, silicon nitride, silicon oxynitride, aluminum oxide, aluminum nitride, aluminum oxynitride, zirconium oxide, zirconium nitride, zirconium oxynitride, titanium oxide, titanium nitride, titanium oxynitride, hafnium oxide, hafnium nitride, hafnium oxynitride, tantalum oxide, tantalum nitride, tantalum oxynitride, lithium fluoride, or a combination thereof, but is not limited thereto. The organic-inorganic film may include, for example, polyorganosiloxane, but is not limited thereto. The encapsulation layer 190 may be one or two or more layers.

The color conversion panel 200 may convert light of a specific wavelength supplied from the light emitting panel 100 into light of a first or second emission spectrum different from the specific wavelength and emit it toward an observer (not shown) and specifically, may include an upper substrate 210, a light blocking pattern 220, a color filter layer 230, a planarization layer 240, a partition wall 250, a color conversion layer 270, and an encapsulation layer 290.

The upper substrate 210 may be a glass substrate or a polymer substrate. The polymer substrate may include, for example, polyimide, polyamide, polyamideimide, polyethylene terephthalate, polyethylene naphthalene, polymethyl methacrylate, polycarbonate, a copolymer thereof, or a combination thereof, but is not limited thereto.

The color conversion layer 270 faces the light emitting device 180 of the light emitting panel 100. The color conversion layer 270 may include at least one color conversion region for converting an emission spectrum of light supplied from the light emitting panel 100 into other emission spectrum, and the color conversion region may, for example, convert light in the emission spectrum supplied from the light emitting panel 100 into light in the emission spectrum of the color displayed by each of the subpixels PX₁, PX₂, and PX₃.

The color conversion region may include a color converting body that converts the emission spectrum of light supplied from the light emitting panel 100 into other emission spectrum, and the display panel according to the embodiment may include the quantum dot composite according to the embodiment in the color conversion region.

The color conversion region may convert it into light having a wavelength spectrum of a color displayed by each of the subpixels PX₁, PX₂, and PX₃ and then may emit it, and accordingly, the quantum dot included in each color conversion region may be different from each other.

Referring to FIG. 5, at least a portion of the color conversion layer 270 may include the quantum dot composite including the quantum dot. For example, the color conversion layer 270 may include a first color conversion region 270a included in the first subpixel PX₁ and including a first quantum dot 271a, a second color conversion region 270b included in the second subpixel PX₂ and including a second quantum dot 271b, and a light transmitting region 270c.

The first quantum dots 271a included in the first color conversion region 270a may convert the light emitted from the light emitting panel 100 into light of the first emission spectrum that is the same as the wavelength spectrum of the color displayed in the first subpixel PX₁. The first emission spectrum may be different from the emission spectrum of the light emitted from the light emitting panel 100 and may have a longer wavelength than the emission spectrum.

The second quantum dot 271b included in the second color conversion region 270b may convert the light emitted from the light emitting panel 100 into the light of the second wavelength spectrum that is the same as the wavelength spectrum of the color displayed in the second subpixel PX₂. The second emission spectrum may be different from the first emission spectrum and may have a longer wavelength than the first emission spectrum.

For example, when the light emitting device 180 of the light emitting panel 100 emits light of a blue emission spectrum, and the first subpixel PX₁, the second subpixel PX₂, and the third subpixel PX₃ respectively displays red, green, and blue, the first quantum dot 271a included in the first color conversion region 270a may convert the light of the blue emission spectrum into light of the red emission spectrum, and the second quantum dot 271b included in the second color conversion region 270b may convert the light of the blue emission spectrum into light of the green emission spectrum. Herein, since the first quantum dot 271a emits light of a longer wavelength spectrum than that of the second quantum dot 271b, the first quantum dot 271a may have a larger size than that of the second quantum dot 271b. The blue displayed in the third subpixel PX₃ may be displayed by the light of the blue emission spectrum emitted from the light emitting device 180 of the light emitting panel 100 and thus displayed through the light transmitting region 270c without a separate color conversion body (quantum dot) in the third subpixel PX₃. However, the third subpixel PX₃ may further include the color conversion body such as a quantum dot emitting light of the blue emission spectrum.

The partition wall 250 may define each region of the color conversion layer 270 and be disposed between adjacent regions. For example, the partition wall 250 may respectively define the aforementioned first and second color conversion regions 270a and 270b and light transmitting region 270c and be disposed between the adjacent first and second color conversion regions 270a and 270b, between the second color conversion region 270b and the light transmitting region 270c which are neighboring each other, and/or between the first color conversion region 270a and the light transmitting region 270c, which are neighboring each other. The partition wall 250 may provide a space to which a composition for the color conversion layer 270 is supplied and simultaneously, prevent each composition for the first color conversion region 270a, the second color conversion region 270b, and the light transmitting region 270c from overflowing into each neighboring first color conversion region 270a, second color conversion region 270b, and light transmitting region 270c during the process of forming the first color conversion region 270a, the second color conversion region 270b, and the light transmitting region 270c.

The partition wall 250 may directly contact the first color conversion region 270a, the second color conversion region 270b, and the light transmitting region 270c without separate layers between the partition wall 250 and the first color conversion region 270a, between the partition wall 250 and the second color conversion region 270b, and between the partition wall 250 and the light transmitting region 270c.

The color filter layer 230 may more precisely filter light emitted from the color conversion layer 270 and thus enhance color purity of the light emitted toward the upper substrate 210. For example, the first color filter 230a overlapped with the first color conversion region 270a may block light not converted by but transmitting the first quantum dot 271a of the first color conversion region 270a and for example, enhance color purity of light of the red emission spectrum. For example, the second color filter 230b overlapped with the second color conversion region 270b may block light not converted by but transmitting the first quantum dot 271b of the second color conversion region 270b and for example, enhance color purity of light of the green emission spectrum. For example, the third color filter 230c overlapped with the second color conversion region 270c may block light other than light of the blue emission spectrum and for example, enhance color purity of light of the blue emission spectrum. For example, at least some of the first, second, and third color filter 230a, 230b, and 230c may be omitted, for example, the third color filter 230c overlapped with the light transmitting region 270c may be omitted.

The light blocking pattern 220 may partition each subpixel PX₁, PX₂, and PX₃ and be disposed between the neighboring subpixels PX₁, PX₂, and PX₃. The light blocking pattern 220 may be, for example, a black matrix. The light blocking pattern 220 may be overlapped with the edges of the neighboring color filters 230a, 230b, and 230c.

The planarization layer 240 may be disposed between the color filter layer 230 and the color conversion layer 270, and may reduce or eliminate a step difference caused by the color filter layer 230. The planarization layer 240 may include an organic material, an inorganic material, an organic-inorganic material, or a combination thereof. The planarization layer 240 may include, for example, an oxide, a nitride, or an oxynitride, for example, silicon oxide, silicon nitride, silicon oxynitride, or a combination thereof, but is not limited thereto. The planarization layer 240 may be one layer or two or more layers, and may cover the whole surface of the upper substrate 210.

The encapsulation layer 290 may cover the color conversion layer 270 and the partition wall 250, and may include a glass plate, a metal thin film, an organic film, an inorganic film, an organic-inorganic film, or a combination thereof. The organic film may include, for example, an acrylic resin, a (meth)acrylic resin, polyisoprene, a vinyl resin, an epoxy resin, a urethane resin, a cellulose resin, a perylene resin, or a combination thereof, but is not limited thereto. The inorganic film may include, for example, an oxides, a nitride, and/or an oxynitride, for example silicon oxide, silicon nitride, silicon oxynitride, aluminum oxide, aluminum nitride, aluminum oxynitride, zirconium oxide, zirconium nitride, zirconium oxynitride, titanium oxide, titanium nitride, titanium oxynitride, hafnium oxide, hafnium nitride, hafnium oxynitride, tantalum oxide, tantalum nitride, tantalum oxynitride, lithium fluoride, or a combination thereof, but is not limited thereto. The organic-inorganic film may include, for example, polyorganosiloxane, but is not limited thereto. The encapsulation layer 290 may be one or two or more layers.

A light transmitting layer 300 may be disposed between the light emitting panel 100 and the color conversion panel 200. The light transmitting layer 300 may be, for example, a filling material. The light transmitting layer 300 may include an organic material, an inorganic material, an organic-inorganic material, or a combination thereof, and may include, for example, an epoxy resin, a silicone compound, a polyorganosiloxane, or a combination thereof.

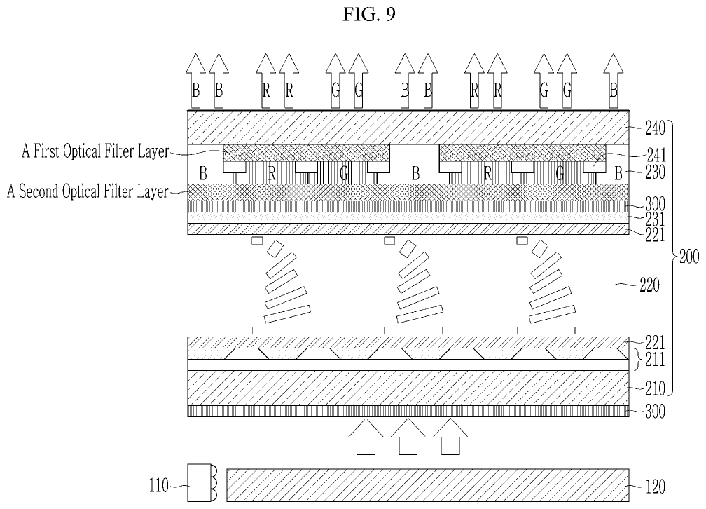

Referring to FIG. 9, as a display device according to a non-limiting embodiment, for example, a liquid crystal display device will be described with reference to the drawing. FIG. 9 is a schematic cross-sectional view of a liquid crystal display device according to a non-limiting embodiment.

Referring to FIG. 9, a display device according to an embodiment includes a liquid crystal panel 200, a polarizing plate 300 disposed under the liquid crystal panel 200, and a backlight unit disposed under the polarizing plate 300. The backlight unit includes a light source 110 and a light guide plate 120. The backlight unit may be in the form of direct lighting without a light guide plate.

The liquid crystal panel 200 includes a lower substrate 210, an upper substrate 240, and a liquid crystal layer 220 between the lower substrate 210 and the upper substrate 240, and a color conversion layer 230 disposed on the upper surface or lower surface of the upper substrate 240. The color conversion layer 230 may include a quantum dot polymer composite according to an embodiment.

The lower substrate 210 referred to as an array substrate may be a transparent insulation material substrate. The substrate is the same as described above. A wire plate 211 is provided on an upper surface of the lower substrate 210. The wire plate 211 may include a plurality of gate wires (not shown) and data wires (not shown) that define a pixel area, a thin film transistor disposed adjacent to a crossing region of gate wires and data wires, and a pixel electrode for each pixel area, but is not limited thereto. Details of such a wire plate are known and are not particularly limited.

A liquid crystal layer 220 is provided on the wiring plate 211. The liquid crystal layer 220 may include an alignment layer 221 on and under the layer 220 to initially align the liquid crystal material included therein. Details (e.g., a liquid crystal material, an alignment layer material, a method of forming liquid crystal layer, a thickness of liquid crystal layer, or the like) of the liquid crystal material and the alignment layer are known and are not particularly limited.

A lower polarizing plate 300 is provided under the lower substrate. Materials and structures of the polarizing plate 300 are known and are not particularly limited. A backlight unit (e.g., emitting blue light) may be disposed under the polarizing plate 300. An upper optical element or the polarizing plate 300 may be provided between the liquid crystal layer 220 and the transparent substrate 240, but is not limited thereto. For example, the upper polarizing plate may be disposed between the liquid crystal layer 220 and the color conversion layer 230. The polarizing plate may be any polarizer that used in a liquid crystal display device. The polarizing plate may be TAC (triacetyl cellulose) having a thickness of less than or equal to about 200 μm, but is not limited thereto. In another embodiment, the upper optical element may be a coating that controls a refractive index without a polarization function.

The light source 110 included in the backlight unit may emit blue light or white light. The light source may include a blue LED, a white LED, a blue OLED, a white OLED, or a combination thereof, but is not limited thereto.

In an embodiment, the backlight unit may be an edge-type lighting. For example, the backlight unit may include a reflector (not shown), a light guide plate (not shown) provided on the reflector and providing a planar light source with the liquid crystal panel 200, and/or at least one optical sheet (not shown) on the light guide plate, for example, a diffusion plate, a prism sheet, and the like, but is not limited thereto. For example, the backlight unit may have a reflector (not shown), and may have a plurality of fluorescent lamps disposed on the reflector at regular intervals, or may have an LED operating substrate on which a plurality of light emitting diodes may be disposed, a diffusion plate thereon, and optionally at least one optical sheet. Details (e.g., each component of a light emitting diode, a fluorescent lamp, a light guide plate, various optical sheets, and a reflector) of such a backlight unit are known and are not particularly limited.

A black matrix 241 is provided under the transparent substrate 240 and has openings and hides a gate line, a data line, and a thin film transistor of the wire plate on the lower substrate. For example, the black matrix 241 may have a grid shape. The color conversion layer 230 is provided in the opening of the black matrix 241 and has a quantum dot-polymer composite pattern including a first region (R) configured to emit first light (e.g., red light), a second region (G) configured to emit second light (e.g., green light), and a third region (B) configured to emit/transmit, for example blue light. If needed, the color conversion layer 230 may further include at least one fourth region. The fourth region may include a quantum dot that emits different color from light emitted from the first to third regions (e.g., cyan, magenta, and yellow light).

In the color conversion layer 230, regions forming the pattern may be repeated corresponding to pixel areas formed on the lower substrate. A transparent common electrode 231 may be provided on the photoluminescent type color conversion layer 230.

The third region (B) configured to emit/transmit blue light may be a transparent color filter that does not change the emission spectrum of the light source. In this case, blue light emitted from the backlight unit may enter in a polarized state and may be emitted through the polarizing plate and the liquid crystal layer as it is. If needed, the third region may include a quantum dot emitting blue light.

If desired, the display device or the light emitting device according to an embodiment may further include an excitation light blocking layer or a first optical filter layer (hereinafter, referred to as a first optical filter layer). The first optical filter layer may be disposed between the bottom surfaces of the first region (R) and the second region (G) and the substrate (e.g., the upper substrate 240) or on the upper surface of the substrate. The first optical filter layer may be a sheet having an opening in a portion corresponding to a pixel region (third region) displaying blue, and thus may be formed in portions corresponding to the first and second regions. Two or more first optical filter layers may be spaced apart from each other at positions overlapped with the first and second regions, and optionally, the third region. When the light source includes a green light emitting element, a green light blocking layer may be disposed on the third region.

The first optical filter layer may block light having, for example, a predetermined wavelength region in the visible light region and may transmit light in the other wavelength regions, and for example, it may block blue light (or green light) and may transmit light except the blue light (or green light). The first optical filter layer may transmit, for example, green light, red light, and/or yellow light which is a mixed color thereof. The first optical filter layer may transmit blue light and block green light, and may be disposed on the blue light emitting pixel.

The display device may further include a second optical filter layer (e.g., recycling layer of red/green light or yellow light) that is disposed between the photoluminescent layer and the liquid crystal layer (e.g., between the photoluminescent layer and the upper polarizer), transmits at least a portion of the third light (excitation light), and reflects at least a portion of the first light and/or the second light. The first light may be red light, the second light may be green light, and the third light may be blue light. The second optical filter layer may transmit only the third light (B) in a blue light wavelength region having a wavelength region of less than or equal to about 500 nm and light in a wavelength region of greater than about 500 nm, which is green light (G), yellow light, red light (R), or the like, may be not passed through the second optical filter layer 140 and reflected. The reflected green light and red light may pass through the first and second regions and to be emitted to the outside of the display device 10.

The second optical filter layer or the first optical filter layer may be formed as an integrated layer having a relatively planar surface.

The first optical filter layer may include a polymer thin film including a dye and/or a pigment absorbing light in a wavelength which is to be blocked. The second optical filter layer and the first optical filter layer may include a single layer having a low refractive index, and may be, for example, a transparent thin film having a refractive index of less than or equal to about 1.4, less than or equal to about 1.3, or less than or equal to about 1.2. The second optical filter layer or the first optical filter layer having a low refractive index may be, for example, a porous silicon oxide, a porous organic material, a porous organic-inorganic composite, or a combination thereof.

The first optical filter layer or the second optical filter layer may include a plurality of layers having different refractive indexes. It may be formed by stacking two layers having different refractive indexes. For example, the first/second optical filter layer may be formed by alternately stacking a material having a high refractive index and a material having a low refractive index.

Hereinafter, the embodiments are illustrated in more detail with reference to examples. However, they are exemplary examples of the present disclosure, and the present disclosure is not limited thereto.

### Examples

### Analysis Methods

### [1] UV-Vis Spectroscopy

UV spectroscopy is performed by using an Agilent Cary5000 spectrometer to obtain a UV-Visible absorption spectrum.

### [2] Photoluminescence Analysis

A Hitachi F-7000 spectrometer is used to obtain photoluminescence (PL) spectra of the prepared quantum dot at excitation wavelength of 450 nm.

### [3] ICP Analysis

Shimadzu ICPS-8100 is used to perform inductively coupled plasma-atomic emission spectrometry (ICP-AES).

### [4] Measurement of Absolute Quantum Efficiency (QE) for Quantum Dot Composite

The quantum efficiency (Quantum Yield (%)) of the coating film using the prepared quantum dot composite ink composition is measured using a quantum efficiency measurement system (QE-2100, Otsuka).

### [5] Method for Measuring Reliability (Luminance) of Quantum Dot-Composite Films

The prepared quantum dot composite composition is coated on a glass substrate to form a film, and a capping layer is formed on the film. Subsequently, this substrate obtained therefrom is fixed on an LED chip, and an appropriate voltage is applied thereto to measure reliability within a desired luminance range.

### Synthesis Example 1: Preparation of Green InP Core

InP semiconductor nanocrystal particles (hereinafter, also referred to as core) were prepared in the following manner.

In a 200 milliliter (mL) reaction flask, indium acetate and palmitic acid were dissolved in 1-octadecene and then, heated at 120° C. under vacuum with a mole ratio of indium and palmitic acid of about 1:3. After 1 hour, the gas atmosphere in the reactor was replaced with nitrogen (N₂). After heating the reactor at 280° C., a mixed solution of tris(trimethylsilyl)phosphine (TMS3P, in an amount of 0.5 moles per mole of indium) and trioctylphosphine was rapidly injected into the reaction mixture and then stirred for 20 minutes. Acetone was added and the reaction mixture was allowed to cool to room temperature. The precipitate was isolated by centrifugation and was dispersed in toluene. The size of the obtained InP core was about 2 nm as determined by measurement with a transmission electron microscope (TEM).

### Synthesis Example 2: Preparation of Green Quantum Dot (InP/ZnSe/ZnS)

Selenium was dispersed in trioctylphosphine to prepare a Se/TOP stock solution, and sulfur was dispersed in trioctylphosphine to prepare a S/TOP stock solution.

In a 200 mL reaction flask, zinc acetate and oleic acid were dissolved in trioctylamine and then, vacuum-treated at 120° C. for 10 minutes. After replacing the gas atmosphere of the reaction flask with N₂, the toluene dispersion of the InP core synthesized in Synthesis Example 1 was injected while the temperature of the obtained solution was raised to 320° C., and then the prepared Se/TOP stock solution was injected several times. The reaction was performed to obtain a reaction solution including particles having a ZnSe shell disposed on the core. The total reaction time was approximately 100 minutes, and the total content of Se used was about 23 moles per mole of indium.

Then, at 320° C., the S/TOP stock solution was injected into the reaction solution. The reaction was performed to obtain a reaction solution including particles in which the ZnS shell is disposed on the ZnSe shell. The total reaction time was 60 minutes, and the total content of sulfur was about 13 moles per mole of indium. Thereafter, the solution was allowed to cool to room temperature, an excess of ethanol was added, and the mixture was centrifuged. The supernatant was discarded, and the precipitate was dried and dispersed in cyclohexyl acetate to obtain an InP/ZnSe/ZnS quantum dot solution.

### Synthesis Example 3: Preparation of Compound for Surface-Modifying Quantum Dot

### (1) Preparation of Compound of Chemical Formula 1-1

A reaction flask was charged with poly(ethylene glycol) (5 moles, average Mn400) (Sigma-Aldrich Co., Ltd.). Succinic anhydride (5 moles, Sigma-Aldrich Co., Ltd.) was added to the reaction flask with stirring under a nitrogen atmosphere. The reaction mixture was stirred with heating at 80° C. for a predetermined time to obtain a compound represented by Chemical Formula 1-1.

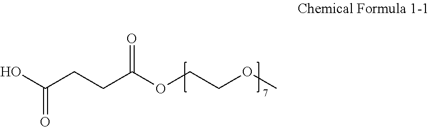

### (2) Preparation of Compound of Chemical Formula 2-1

A compound represented by Chemical Formula 2-1 was purchased from Sigma-Aldrich Co., Ltd.

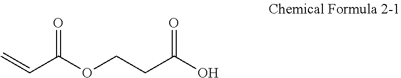

### (3) Preparation of Compound Having Thiol Group (—SH)

Thioglycolic acid (50 g), 2-[2-(2-methoxyethoxy)ethoxy]-ethanol (91 g), and p-toluene sulfonic acid monohydrate (10.27 g) were added in a flask and then, dispersed evenly in 500 mL of cyclohexane under a nitrogen atmosphere. A Dean-Stark trap and a condenser were connected to the flask. After heating at 80° C. with stirring, water began to collect inside the Dean-Stark trap. Once the water began to collect in the Dean-Stark trap, the reaction mixture was stirred for an additional 12 hours. After 0.54 moles of water were collected, ethyl acetate and excess of water were added to the reaction mixture. The mixture was concentrated with a vacuum evaporator, and the compound represented by Chemical Formula A was dried in a vacuum oven.

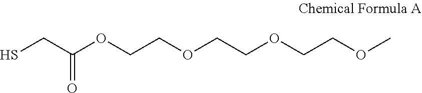

### Example 1: Preparation of Surface-Modified Green Quantum Dot

A 3-necked round bottom flask equipped with a magnetic stir bar was charged with a cyclohexyl acetate solution of the green quantum dots (InP/ZnSe/ZnS) according to Synthesis Example 2 (a quantum dot content: about 26 wt % to 27 wt %). Subsequently, after adding 5 mol % of zinc chloride (ZnCl₂) based on the quantity of the compound represented by Chemical Formula 1-1 prepared according to (1) of Synthesis Example 3 to be added, the compound represented by Chemical Formula 1-1 was added at a ratio of 700 times the moles of the quantum dots. The mixture was stirred at 0° C. under a nitrogen atmosphere for 4 hours. After 4 hours, the compound represented by Chemical Formula 2-1 prepared according to (2) of Synthesis Example 3 was added at a ratio of 0.5 times as many moles as the compound represented by Chemical Formula 1-1. The reaction mixture was then stirred for 20 hours.

The reaction solution was allowed to cool to room temperature and then, cyclohexane was added to precipitate the quantum dots. The precipitated quantum dots were separated through centrifugation and dried in a vacuum oven for a day to obtain surface-modified quantum dots including the compounds represented by Chemical Formulas 1-1 and 2-1 on the surface.

### Example 2: Preparation of Surface-Modified Green Quantum Dot

Surface-modified quantum dots were prepared in the same manner as in Example 1 except that the compound represented by Chemical Formula 2-1 was added in a 1:1 mole ratio with the compound represented by Chemical Formula 1-1.

### Example 3: Preparation of Surface-Modified Green Quantum Dot

Surface-modified quantum dots were prepared in the same manner as in Example 1 except that the compound represented by Chemical Formula 2-1 were added at a ratio of 1.5 times the moles of the compound represented by Chemical Formula 1-1.

### Example 4: Preparation of Surface-Modified Green Quantum Dot

Surface-modified quantum dots were prepared in the same manner as in Example 1 except that the compound represented by Chemical Formula 2-1 was added at a ratio of 2.5 times the moles of the compound represented by Chemical Formula 1-1.

### Comparative Example 1: Preparation of Surface-Modified Green Quantum Dot

Surface-modified quantum dots were prepared in the same manner as in Example 1 except that the compound represented by Chemical Formula 1-1 was added without the compound represented by Chemical Formula 2-1, and the resulting material was stirred for 24 hours in total.

### Comparative Example 2: Preparation of Surface-Modified Green Quantum Dot

Quantum dots were surface-modified in the same manner as in Example 1 except that the compound represented by Chemical Formula 2-1 was added at a ratio of 3.5 times.

Herein, after allowing the reaction solution to cool to room temperature and adding cyclohexane, the quantum dots did not precipitate.

### Comparative Example 3: Preparation of Surface-Modified Green Quantum Dot

Surface-modified quantum dots were prepared in the same manner as in Example 1 except that the compound represented by Chemical Formula A according to the (3) of Synthesis Example 3 was added instead of the compound represented by Chemical Formula 1-1, the compound represented by Chemical Formula 2-1 was added in a 1:1 mole ratio with the compound represented by Chemical Formula A.

### Comparative Example 4: Preparation of Surface-Modified Green Quantum Dot

Surface-modified quantum dots were prepared in the same manner as in Example 1 except that the compound represented by Chemical Formula A according to the (3) of Synthesis Example 3 was added instead of the compound represented by Chemical Formula 1-1 without the compound represented by Chemical Formula 2-1, and the resulting material was stirred for 24 hours in total.

### Preparation Example 1: Preparation of Surface-Modified Green Quantum Dot Ink Composition

The quantum dots according to Examples 1 to 4 and Comparative Examples 1, 3, and 4 were respectively weighed and mixed with a monomer represented by Chemical Formula B (1,6-hexanediol diacrylate, Sigma-Aldrich Co., Ltd.) and then, stirred for about 1 hour, and a polymerization inhibitor (methylhydroquinone, Tokyo Chemical Industry Co. Ltd.) was added thereto and then, stirred for 5 minutes. Subsequently, a photoinitiator (TPO-L, Polynetron) and a diffuser (TiO₂, SDT89, Iridos) were added thereto. The entire dispersion was stirred for 1 hour to prepare a solvent-free quantum dot ink composition.

Based on a total weight of the solvent-free quantum dot ink composition, the surface-modified quantum dots according to the examples and the comparative examples were included in an amount of 48 wt %, the monomer represented by Chemical Formula B was included in an amount of 40 wt %, the polymerization inhibitor was included in an amount of 1 wt %, the photoinitiator was included in an amount of 3 wt %, and the light diffuser was included in an amount of 8 wt %.

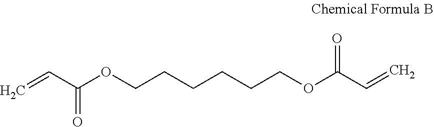 [SMILES: C=CC(=O)OCCCCCCOC(=O)C=C]

### Preparation Example 2: Preparation of Single Film from Quantum Dot Ink Composition

Each of the ink compositions of Preparation Example 1 respectively including the surface-modified green quantum dots of the examples and the comparative examples were coated on a glass substrate to a thickness of about 10 μm with a spin coater (800 rotations per minute (rpm), 5 seconds, Opticoat MS-A150, Mikasa Co., Ltd.), exposed at 4,000 millijoules (mJ) under a nitrogen atmosphere with a 395 nm ultraviolet (UV) exposer, and heat-treated (post-baked) at 180° C. for 30 minutes to obtain each quantum dot composite film.

### Evaluation 1: Measurement of Quantum Efficiency

Each film prepared in Preparation Example 2 was cut to prepare a single film specimen with a size of 2 cm×2 cm and was then loaded in a quantum efficiency measurement system (QE-2100, Otsuka Electronics Co., Ltd.) to measure quantum efficiency (EQ) (or quantum yield (%)), and the results are provided in Table 1.

### Evaluation 2: Driving Reliability Experiment

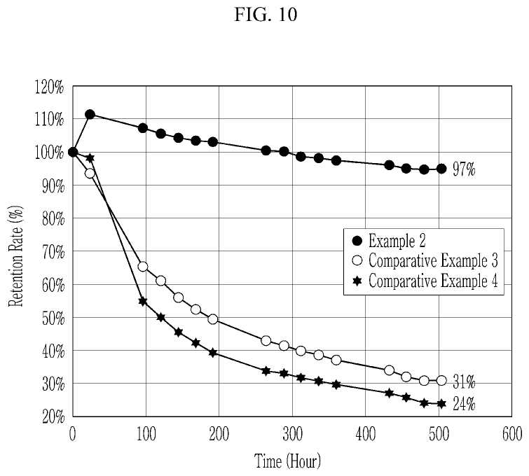

Each film prepared in Preparation Example 2 was measured with respect to luminance, while driving by using a light source (wavelength: 450 nm) with luminance of about 140,000 nits at room temperature under air conditions for 500 hours to irradiate excitation light, and the results are provided in Table 1. In addition, FIG. 10 illustrates the luminance maintenance rate to initial luminance of each of the quantum dot composite single films of Example 2 and Comparative Examples 3 and 4 over time according to the irradiation of the excitation light.

TABLE 1

| | Luminance maintenance rate | Quantum efficiency |
|---|---|---|
| | after 500 hours of operation | (QE) |
| Example 1 | 95% | 28.0% |
| Example 2 | 97% | 26.0% |
| Example 3 | 96% | 27.0% |
| Example 4 | 98% | 30.8% |
| Comparative Example 1 | 75% | 28.6% |
| Comparative Example 2 | surface modification was not possible | |
| Comparative Example 3 | 31% | 31.8% |
| Comparative Example 4 | 24% | 32.6% |

As shown in Table 1, each of the single films formed of quantum dot composites including the quantum dots of Examples 1 to 4 with the compounds represented by Chemical Formulas 1 and 2 in a mole ratio range of 1:0.5 to 1:2.5 on the surface of the quantum dot exhibited quantum efficiencies (QE) of about 26% to about 31% and also, a luminance maintenance rate of 95% or more after driving with a light source of about 140,000 nit for 500 hours, which confirms the high reliability for maintaining luminance after driving for a long time under high luminance conditions for the films.

The single film including the quantum dots of Comparative Example 1 including the compound represented by Chemical Formula 1 alone on the surface of the quantum dots exhibited almost the same quantum efficiency (QE) as the single films according to Examples 1 to 4 but a luminance maintenance rate of only 75% after driving with the light source of about 140,000 nit for 500 hours, which illustrates the inferior reliability of the film in comparison to the single films according to Examples 1 to 4.

For Comparative Example 2, the quantum dots were treated by mixing the compounds represented by Chemical Formulas 1 and 2 in a mole ratio of 1:3.5 but were not surface-modified with the compounds because the quantum dots failed to precipitate during preparation. A quantum dot composite single film was not prepared therefrom.

Comparative Example 3 was the result of a quantum dot composite single film including quantum dots surface-modified by using a thiol-based compound represented by Chemical Formula A and a compound represented by Chemical Formula 2 in a mole ratio of 1:1 instead of the compound represented by Chemical Formula 1. This single film exhibits almost the same quantum efficiency (QE) as the single films of Examples 1 to 4 but a luminance maintenance rate of only 31%, which confirms a decreased reliability for luminance maintenance.

Comparative Example 4 exhibited the result of a quantum dot composite single film formed of the quantum dots including the thiol-based compound represented by Chemical Formula A alone without any compound represented by Chemical Formula 1 or 2. This single film exhibited almost the same quantum efficiency (QE) as the single films of Examples 1 to 4 but a luminance maintenance rate of only 24%, which is the lowest among the examples and the comparative examples. Accordingly, the quantum dots including the thiol-based compound represented by Chemical Formula A alone exhibited very low reliability for luminance maintenance when driving under high luminance conditions.

FIG. 10 is a graph showing each luminance maintenance rate relative to initial luminance over time of the quantum dot composite single films prepared in Example 2 and Comparative Example 3 and 4, while being excited using a blue LED of about 140,000 nit and operated for 500 hours.

Referring to FIG. 10, the single films of a quantum dot composite including the quantum dots including the compound represented by Chemical Formula 2 with the compound represented by Chemical Formula 1 on the surface according to an embodiment exhibited a high luminance maintenance rate of about 97% even when driving with high luminance of about 140,000 nit for a long time of 500 hours, which confirms high luminance reliability.

On the contrary, the single films including the quantum dots according to Comparative Examples 3 and 4 exhibited a luminance maintenance rate of less than 70%, which is already deteriorated by greater than 30% from the initial luminance just after 100 hours when driving for 500 hours under the same high luminance conditions and also, deteriorated to less than 50% after 200 hours and thus confirms the low reliability for luminance maintenance under the high luminance conditions for the comparative examples.

Accordingly, the quantum dot and the quantum dot composite including the same according to disclosed embodiments are particularly applicable to various light sources, particularly, electronic apparatus including light sources requiring high luminance, for example, display devices such as AR and VR with improved characteristics of luminance maintenance and suitable quantum efficiency.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A quantum dot, comprising
a core comprising a semiconductor nanocrystal comprising indium (In) and phosphorus (P),
a shell disposed on the core and comprising a semiconductor nanocrystal, and
a compound represented by Chemical Formula 1 and a compound represented by Chemical Formula 2, both of which are present on the surface of the shell: 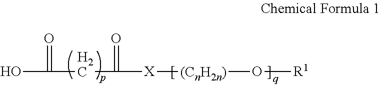
wherein, in Chemical Formula 1,
X is O or NR^{a}, wherein R^{a} is hydrogen or a C1 to C10 alkyl group,
R¹ is hydrogen, a substituted or unsubstituted C1 to C20 alkyl group, a substituted or unsubstituted C2 to C20 alkenyl group, a substituted or unsubstituted C3 to C20 cycloalkyl group, or a substituted or unsubstituted C1 to C20 alkoxy group, and
p, q, and n are each independently an integer from 1 to 20; 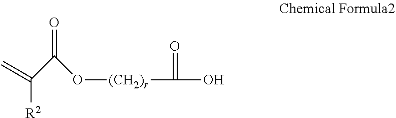
wherein, in Chemical Formula 2,
R² is hydrogen or a substituted or unsubstituted C1 to C20 alkyl group, and
r is an integer from 1 to 10.

2. The quantum dot of claim 1, wherein in Chemical Formula 1, X is O or NH, R¹ is hydrogen, or a substituted or unsubstituted C1 to C5 alkyl group, p and n are each independently an integer from 1 to 5, and q is an integer from 2 to 10.

3. The quantum dot of claim 1, wherein in Chemical Formula 2, R² is hydrogen, or a substituted or unsubstituted C1 to C10 alkyl group, and r is an integer from 2 to 10.

4. The quantum dot of claim 1, wherein the compound represented by Chemical Formula 1 and the compound represented by Chemical Formula 2 are present on the surface of the quantum dot in a mole ratio of about 1:0.5 to about 1:3.

5. The quantum dot of claim 1, wherein the quantum dot further comprises a compound represented by RCOOH, RNH₂, R₂NH, R₃N, RSH, RH₂PO, R₂HPO, R₃PO, RH₂P, R₂HP, R₃P, ROH, RCOOR′, RPO(OH)₂, or R₂POOH {wherein R and R′ each independently comprise a substituted or unsubstituted C1 to C40 aliphatic hydrocarbon group, a substituted or unsubstituted C3 to C30 alicyclic hydrocarbon group, or a substituted or unsubstituted C6 to C40 aromatic hydrocarbon group, or a combination thereof}, or a combination thereof on the surface of the shell.

6. The quantum dot of claim 1, wherein the quantum dot has a peak emission wavelength of about 500 nanometers to about 550 nanometers and does not comprise cadmium.

7. The quantum dot of claim 1, wherein the semiconductor nanocrystal included in the shell comprises zinc (Zn) and selenium (Se).

8. The quantum dot of claim 7, wherein the semiconductor nanocrystal included in the shell further comprises sulfur (S).

9. The quantum dot of claim 1, wherein the shell comprises a first semiconductor nanocrystal shell disposed on the core and comprising zinc and selenium, and a second semiconductor nanocrystal shell disposed on the first semiconductor nanocrystal shell and comprising zinc and sulfur.

10. A composition for preparing a quantum dot composite, comprising
the quantum dot of claim 1, and
at least one of a dispersant and a polymerizable monomer comprising a carbon-carbon unsaturated bond.

11. The composition of claim 10, wherein the composition further comprises a thiol compound having at least one thiol group at a terminal end, metal oxide particulates, or a combination thereof.

12. The composition of claim 10, wherein the dispersant is an organic compound comprising a carboxyl group, and comprises a combination of monomers comprising a first monomer having a carboxyl group and a carbon-carbon double bond, a second monomer having a carbon-carbon double bond and a hydrophobic moiety and not comprising a carboxyl group, and optionally a third monomer having a carbon-carbon double bond and a hydrophilic moiety, and not comprising a carboxyl group, or a copolymer thereof; a polymer containing multiple aromatic rings having a carboxyl group and having a skeletal structure in which two aromatic rings in the main chain are bound to quaternary carbon atoms that are constituent atoms of other cyclic moieties; or a combination thereof.

13. The composition of claim 11, wherein the metal oxide particulates comprise TiO₂, SiO₂, BaTiO₃, Ba₂TiO₄, ZnO, or a combination thereof.

14. The composition of claim 10, wherein an amount of the quantum dot in the composition is about 1 weight percent to about 50 weight percent, and a sum of an amount of the compound represented by Chemical Formula 1 and an amount of the compound represented by Chemical Formula 2 is about 1 weight percent to about 50 weight percent, based on a total weight of the composition.

15. A quantum dot composite, comprising
a polymer matrix, and
a plurality of quantum dots dispersed in the polymer matrix,
wherein the quantum dot composite is configured to emit green light, and
wherein the plurality of quantum dots comprise a semiconductor nanocrystal core comprising indium and phosphorus, a shell disposed on the core and comprising a semiconductor nanocrystal, and a compound represented by Chemical Formula 1 and a compound represented by Chemical Formula 2 or a moiety therefrom present on the surface of the shell: 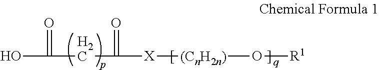
wherein, in Chemical Formula 1,
X is O or NR^{a}, wherein R^{a} is hydrogen or a C1 to C10 alkyl group,
R¹ is hydrogen, a substituted or unsubstituted C1 to C20 alkyl group, a substituted or unsubstituted C2 to C20 alkenyl group, a substituted or unsubstituted C3 to C20 cycloalkyl group, or a substituted or unsubstituted C1 to C20 alkoxy group, and
p, q, and n are each independently an integer from 1 to 20; 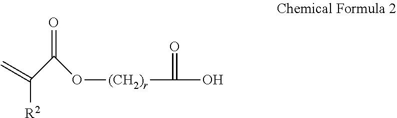
wherein, in Chemical Formula 2,
R² is hydrogen or a substituted or unsubstituted C1 to C20 alkyl group, and
r is an integer from 1 to 10.

16. The quantum dot composite of claim 15, wherein the semiconductor nanocrystal included in the shell comprises zinc, selenium, and sulfur, and the quantum dot is included in an amount of about 1 weight percent to about 50 weight percent based on a total weight of the quantum dot composite.

17. The quantum dot composite of claim 15, wherein the quantum dot composite exhibits greater than or equal to about 90% relative to its initial luminance value when driven for about 500 hours with blue light of about 140,000 nits.

18. A display panel comprising the quantum dot composite prepared from the composition for preparing a quantum dot composite of claim 15.

19. The display panel of claim 18, wherein the display panel comprises a color conversion layer comprising a plurality of regions comprising a color conversion region, and the quantum dot composite is disposed in the color conversion region in the color conversion layer.

20. The display panel of claim 18, wherein the display panel further comprises a light emitting panel comprising a light emitting source, and the color conversion layer converts an emission spectrum of light emitted from the light emitting panel.
